(19) United States
(12) Patent Application Publication
(10) Pub. No.: US 2008/0206907 A1
(43) Pub. Date: Aug. 28, 2008

(54) Method for fabricating semiconductor device to which test is performed at wafer level and apparatus for testing semiconductor device

(76) Inventors: Norihiko Shishido, Yokohama-shi (JP); Katsu Honna, Kawasaki-shi (JP); Hiroto Kotori, Kitakyushu-shi (JP); Shigekazu Miura, Yokohama-shi (JP)

Correspondence Address: SPRINKLE IP LAW GROUP, 1301 W. 25TH STREET, SUITE 408, AUSTIN, TX, 78705, US

(21) Appl. No.: 11/986,450

(22) Filed: Nov. 21, 2007

(30) Foreign Application Priority Data
Nov. 22, 2006 (JP) 2006-315655

(51) Int. Cl. H01L 21/66; G01R 31/26

(52) U.S. Cl. 438/17; 324/760; 257/E21.531

(57) ABSTRACT

A method for fabricating a semiconductor device includes placing a semiconductor wafer on a stage, the semiconductor wafer having a plurality of ball-shaped external connecting terminals projected from a surface, bringing a probe card close to the semiconductor wafer placed on the stage to bring a plurality of probe terminals included in the probe card into contact with the external connecting terminals respectively, and applying a voltage to the semiconductor wafer through the probe terminal to perform a test of the semiconductor wafer. The probe terminals contact all the external connecting terminals.

### CROSS-REFERENCE TO RELATED APPLICATIONS

This application is based upon and claims the benefit of priority from prior Japanese Patent Application No. 2006-315655, filed Nov. 22, 2006, the entire contents of which are incorporated herein by reference.

### BACKGROUND OF THE INVENTION

1. Field of the Invention

The present invention relates to a method for fabricating a semiconductor device at a wafer level and an apparatus for testing the semiconductor device. For example, the invention relates to an LSI fabricating method including a burn-in test process at a wafer level.

2. Description of the Related Art

Usually the semiconductor device fabricating process includes the burn-in test process. In the burn-in test, an operation test is performed on the semiconductor device while a voltage is applied and a temperature is raised, thereby screening the defective semiconductor device.

Conventionally, the burn-in test is performed while the individual semiconductor chip is packaged. On the other hand, in the field of semiconductor memory, recently there is proposed a technique of collectively performing the burn-in test at the wafer level. For example, Japanese Patent No. 3293995 discloses the technique.

However, a system LSI has extremely numerous external connecting terminals as compared with the semiconductor memory. Therefore, the burn-in test is hardly performed on the system LSI at the wafer level, and currently research and development of the burn-in test is not well progressed for the system LSI at the wafer level.

### BRIEF SUMMARY OF THE INVENTION

A method for fabricating a semiconductor device according to an aspect of the present invention includes:

placing a semiconductor wafer on a stage, the semiconductor wafer having a plurality of ball-shaped external connecting terminals projected from a surface;

bringing a probe card close to the semiconductor wafer placed on the stage to bring a plurality of probe terminals included in the probe card into contact with the external connecting terminals respectively; and

applying a voltage to the semiconductor wafer through the probe terminal to perform a test of the semiconductor wafer, the probe terminals contacting all the external connecting terminals.

A semiconductor device testing apparatus which performs a burn-in test to a semiconductor chip in a wafer state, the semiconductor chip having a plurality of ball-shaped external connecting terminals projected from a surface, the apparatus according to an aspect of the present invention includes:

a stage on which a semiconductor wafer including the semiconductor chip is placed;

a probe card which has a plurality of probe terminals arrayed two-dimensionally at equal intervals, the probe terminals being able to contact the external connecting terminals of the semiconductor wafer placed on the stage;

a power supply unit which generates a voltage; and

an inspection board which applies the voltage generated by the power supply unit to the individual probe terminal.

### BRIEF DESCRIPTION OF THE SEVERAL VIEWS OF THE DRAWING

FIG. 1 is a flowchart showing a semiconductor device fabricating method according to a first embodiment of the invention;

FIG. 2 is perspective and sectional views showing a wafer in a wafer process of the semiconductor device fabricating method according to the first embodiment;

FIG. 3 is perspective and sectional views showing the wafer in a WCSP process of the semiconductor device fabricating method according to the first embodiment;

FIG. 4 is a plan view showing a ball arrangement of the wafer according to the first embodiment;

FIG. 5 is a schematic view showing a state of a burn-in test in the semiconductor device fabricating method according to the first embodiment;

FIG. 6 is a perspective view showing the wafer in a dicing process of the semiconductor device fabricating method according to the first embodiment;

FIG. 7 is a block diagram showing a semiconductor device testing apparatus according to the first embodiment of the invention;

FIG. 8 is a perspective view showing a probe card included in the semiconductor device testing apparatus according to the first embodiment;

FIG. 9 is a plan view showing the probe card included in the semiconductor device testing apparatus according to the first embodiment;

FIG. 10 is a perspective view showing an inspection board and the probe card included in the semiconductor device testing apparatus according to the first embodiment;

FIG. 11 is a flowchart showing the burn-in test in the semiconductor device fabricating method according to the first embodiment;

FIGS. 12 and 13 are sectional views showing the wafer and probe card during the burn-in test according to the first embodiment;

FIG. 14 is a sectional view showing the wafer and probe card during the burn-in test of the first embodiment;

FIG. 15 is a perspective view showing a probe card included in a semiconductor device testing apparatus according to a second embodiment of the invention;

FIG. 16 is a sectional view showing the probe card included in the semiconductor device testing apparatus according to the second embodiment;

FIG. 17 is a plan view showing a back surface of an inspection board included in the semiconductor device testing apparatus according to the second embodiment;

FIG. 18 is a sectional view showing particularly the inspection board, the probe card, and a stage of the semiconductor device testing apparatus according to the second embodiment;

FIG. 19 is a block diagram showing a semiconductor device testing apparatus according to a third embodiment of the invention;

FIG. 20 is a block diagram showing a semiconductor device testing apparatus according to a modification of the third embodiment;

FIG. 21 is a block diagram showing a semiconductor device testing apparatus according to a fourth embodiment of the invention;

FIG. 22 is a sectional view showing a wafer and a probe card during a burn-in test according to the fourth embodiment;

FIG. 23 is a block diagram showing a semiconductor device testing apparatus according to a modification of the fourth embodiment;

FIG. 24 is a block diagram showing a semiconductor device testing apparatus according to a fifth embodiment of the invention;

FIG. 25 is a block diagram showing a semiconductor device testing apparatus according to a modification of the fifth embodiment;

FIGS. 26 to 28 are plan views showing a wafer according to a sixth embodiment of the invention;

FIGS. 29 and 30 are sectional views showing the wafer having a ball arrangement shown in FIG. 28 and a probe card;

FIG. 31 is a plan view showing the wafer according to the sixth embodiment;

FIGS. 32 and 33 are sectional views showing the wafer having a ball arrangement shown in FIG. 31 and the probe card;

FIG. 34 is a sectional view showing an inspection board and a probe card included in a semiconductor device testing apparatus according to a seventh embodiment of the invention;

FIG. 35 is a sectional view showing the inspection board, the probe card, and a stage included in the semiconductor device testing apparatus according to the seventh embodiment;

FIG. 36 is a sectional view showing the inspection board and the probe card included in the semiconductor device testing apparatus according to the seventh embodiment;

FIG. 37 is a sectional view showing the inspection board, the probe card, and the stage included in the semiconductor device testing apparatus according to the seventh embodiment;

FIG. 38 is a sectional view showing a probe card according to a first modification of the first to seventh embodiments;

FIG. 39 is a plan view showing a probe card according to a second modification of the first to seventh embodiments;

FIG. 40 is a sectional view showing QFP according to a third modification of the first to seventh embodiments;

FIG. 41 is a sectional view showing a PGA according to a fourth modification of the first to seventh embodiments;

FIG. 42 is a sectional view showing a BGA according to a fifth modification of the first to seventh embodiments;

FIG. 43 is a block diagram showing a semiconductor device testing apparatus according to a sixth modification of the first to seventh embodiments;

FIGS. 44 and 45 are schematic views of a burn-in test according to an eighth embodiment of the present invention and show a state when the burn-in test is performed on a BGA in which packaging is completed;

FIGS. 46 and 47 are schematic views of a burn-in test according to an eighth embodiment of the present invention and show a state when the burn-in test is performed on a BGA which is not separated into individual packages yet;

FIGS. 48 and 49 are schematic views of a burn-in test according to an eighth embodiment of the present invention and show a state when the burn-in test is performed on a QFP in which the packaging is completed; and

FIGS. 50 and 51 are schematic views of a burn-in test according to an eighth embodiment of the present invention and show a state when the burn-in test is performed on a QFP which is not separated into the individual packages yet.

### DETAILED DESCRIPTION OF THE INVENTION

### First Embodiment

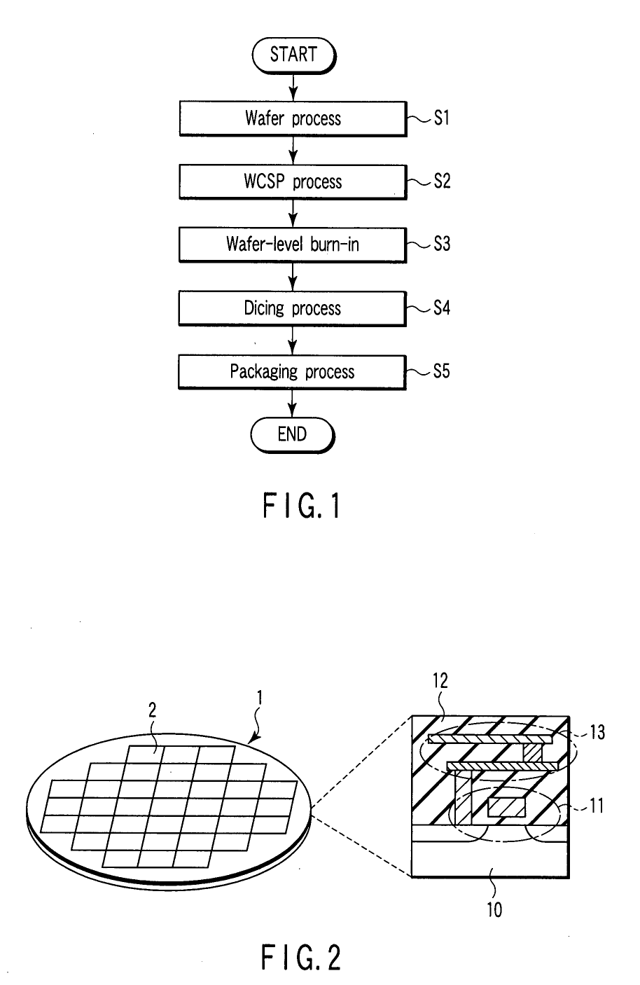

A semiconductor device fabricating method and a semiconductor device testing apparatus according to a first embodiment of the present invention will be described below. The first embodiment relates to the fabricating method, in which formation of a semiconductor element and the burn-in test are performed in the wafer state (referred to as wafer level) and dicing is performed after the burn-in test to fabricate a final product. FIG. 1 is a flowchart showing a rough flow of the semiconductor device fabricating method according to the first embodiment.

As shown in FIG. 1, a wafer process is performed (Step S1). In the wafer process, the semiconductor element (circuit forming the system LSI) is formed on a semiconductor substrate at the wafer level. FIG. 2 is a schematic view showing the wafer process, and FIG. 2 shows an appearance of the wafer and a partial section of the wafer. Plural semiconductor integrated circuit chips (hereinafter simply referred to as chip) included in one wafer shall be referred to as chip even before the chip is cut out from the wafer.

As shown in FIG. 2, a wafer 1 includes plural chips 2. Each chip has the following configuration: A semiconductor element 11 is formed on a semiconductor substrate 10. FIG. 2 shows the case in which the semiconductor element 11 is a MOS transistor. An interlayer dielectric film 12 is formed on the semiconductor substrate 10 such that the semiconductor element 11 is covered with the interlayer dielectric film 12, and a multilayer metal interconnection layer 13 is formed in the interlayer dielectric film 12.

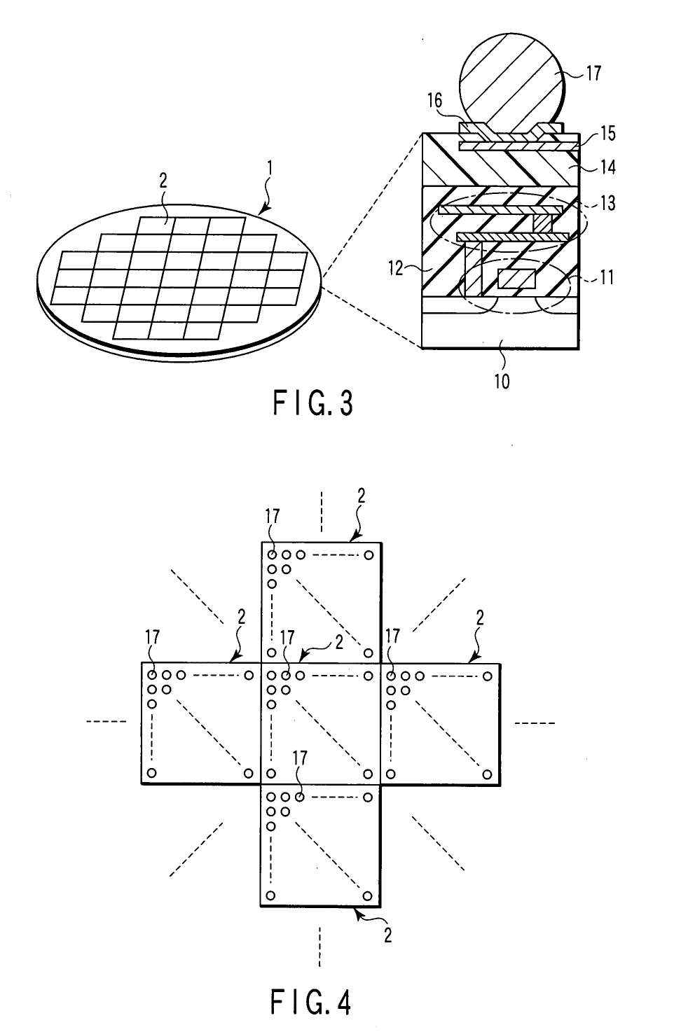

A packaging process is performed at the wafer level after the wafer process (Step S2 of FIG. 1). Hereinafter the packaging process at the wafer level is referred to as WCSP process. In the WCSP process, the packaging is performed at the wafer level to the wafer 1 in which the semiconductor element is formed in step S1. That is, the WCSP process is one in which rewiring and external connecting terminal functioning as a connecting terminal to the outside of the package are formed at the wafer level. FIG. 3 is a schematic view showing the WCSP process, and FIG. 3 shows the appearance of the wafer 1 and the partial section of the wafer 1.

As shown in FIG. 3, a sealing resin 14 is formed on the interlayer dielectric film 12 in a surface of the wafer 1. A rewiring metal interconnection layer 15 is formed in the resin 14. The rewiring metal interconnection layer 15 is used to draw the metal interconnection layer 13 to the outside. An external connecting terminal 17 is formed on the rewiring metal interconnection layer 15 via a metal layer 16. The external connecting terminal 17 is formed in a ball shape while projected from the surface of the resin 14, and a degree of projection becomes larger as compared with the case in which a bump is used as the external connecting terminal. Hereinafter the external connecting terminal 17 is referred to as a ball. As a result, the wafer 1 in which the packaging is performed while the plural balls 17 projected from the surface are arrayed is completed.

FIG. 4 is a plan view showing the wafer 1 in which the packaging is performed through step S2, and FIG. 4 shows arrangement of the balls 17 provided in each chip 2. As shown in FIG. 4, the plural balls 17 are arrayed in a two-dimensional manner on the chip 2. Such a package is known as a wafer-level chip-size package (WCSP). The distance between adjacent balls 17 is equalized.

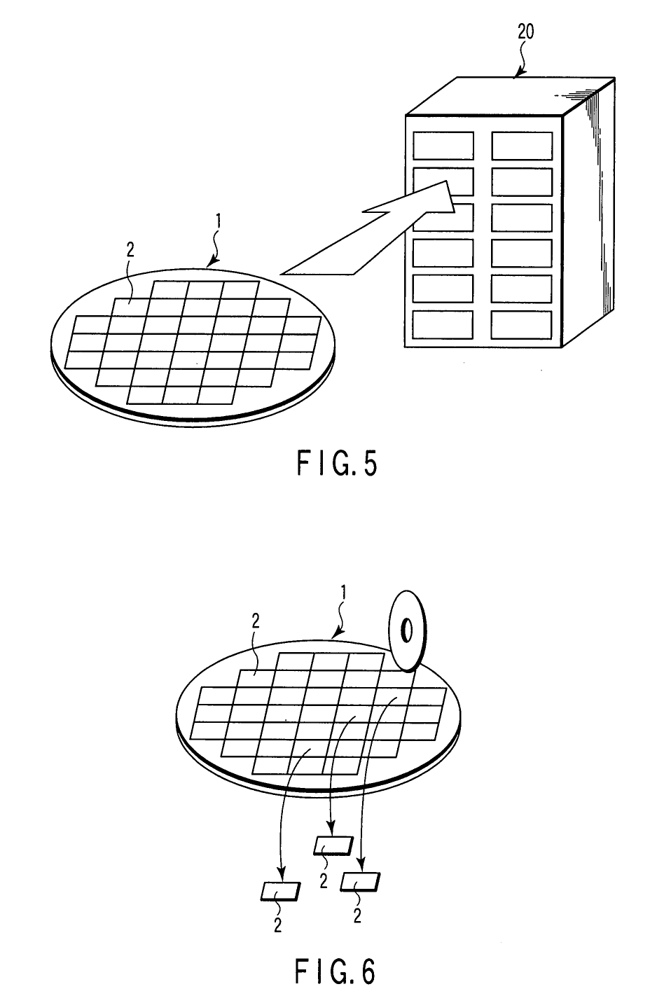

After step S2, the burn-in test is performed at the wafer level (Step S3 of FIG. 1). Step S3 is referred to as wafer-level burn-in. FIG. 5 is a schematic view showing the state of the wafer-level burn-in. As shown in FIG. 5, the wafer 1 is put in a burn-in apparatus 20 which performs the burn-in. In the burn-in apparatus 20, the burn-in test is performed by raising the temperature of the wafer 1 and applying the voltage to the wafer 1, thereby screening the defective chip.

A dicing process is performed after the burn-in test (Step S4 of FIG. 1). In the dicing process, the chip is cut out from the wafer 1. FIG. 6 shows the state of the dicing process. FIG. 6 is a schematic view showing the dicing process. As shown in FIG. 6, the wafer 1 is divided into the individual chips 2. Then, a final packaging process is performed on the individual chip 2 (Step S5 of FIG. 1) to complete a system LSI product.

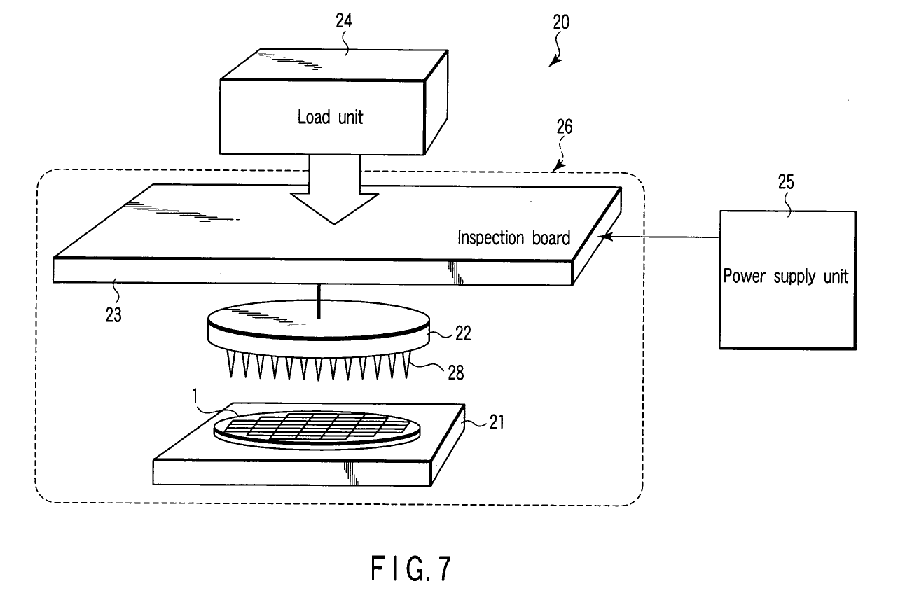

The detailed burn-in test will be described below. First a configuration of the burn-in apparatus 20 will be described. FIG. 7 is a block diagram showing the semiconductor device testing apparatus 20. As shown in FIG. 7, the burn-in apparatus 20 includes a stage 21, a probe card 22, an inspection board 23, a load unit 24, a power supply unit 25, and an oven 26.

During the burn-in test, the wafer 1 is placed on the stage 21. The probe card 22 includes plural probe terminals 28. Each of the probe terminals 28 contacts the ball 17 of the wafer 1. The inspection board 23 is connected to the probe card 22 to apply the voltage or various signals to each of the probe terminals 28 in the probe card 22. The inspection board 23 is prepared in each kind of the wafer 1 to be tested, and the probe card 22 is fixed to the inspection board 23. The load unit 24 applies a load to the probe card 22 while the inspection board 23 is interposed. The load brings the probe terminal 28 of the probe card 22 into contact with the ball 17. The power supply unit 25 generates the voltage and signal necessary for the test, e.g., a power supply voltage Vcc, a ground voltage GND, and a clock signal CLK, and the power supply unit 25 supplies the voltage and signal to the inspection board 23. The oven 26 is formed such that the stage 21, the wafer 1, the probe card 22, and the inspection board 23 can be accommodated therein. The oven 26 heats the stage 21, the wafer 1, the probe card 22, and the inspection board 23 to a setting temperature, which allows the wafer 1 to be heated to the temperature necessary for the burn-in test.

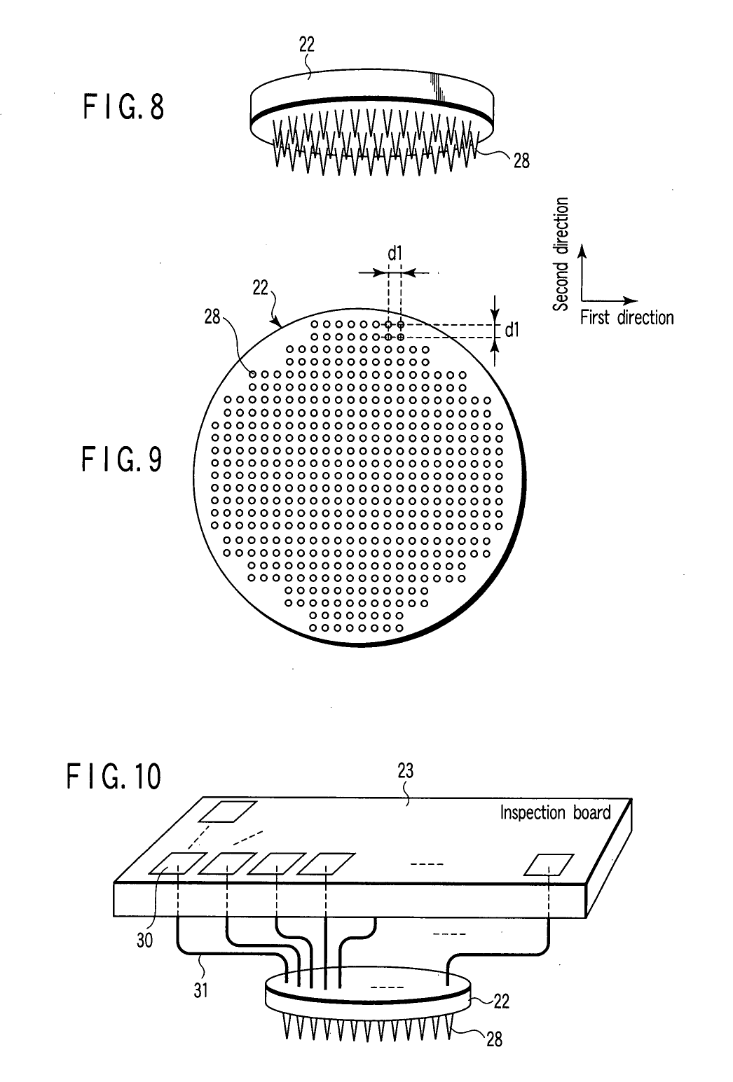

The detailed configuration of the probe card 22 will be described with reference to FIGS. 8 and 9. FIGS. 8 and 9 are perspective and plan views showing the probe card 22 respectively, and FIGS. 8 and 9 show the surface in which the probe terminals 28 are provided.

As shown in FIG. 8, the plural needle-shaped probe terminals 28 are provided in the surface of the probe card 22. The plural probe terminals 28 are two-dimensionally arrayed at equal intervals. That is, the distance between the adjacent probe terminals 28 is set to d1 in both a first direction in the surface and a second direction orthogonal to the first direction. In the wafer 1 of FIGS. 3 and 4, the interval between the adjacent balls 17 is equal to the distance d1 between the probe terminals 28 or equal to a multiple number of d1. Although the probe terminals 28 are arrayed in a matrix shape in FIG. 9, the probe terminals 28 may be arrayed in a zigzag manner. The same holds true for the balls 17.

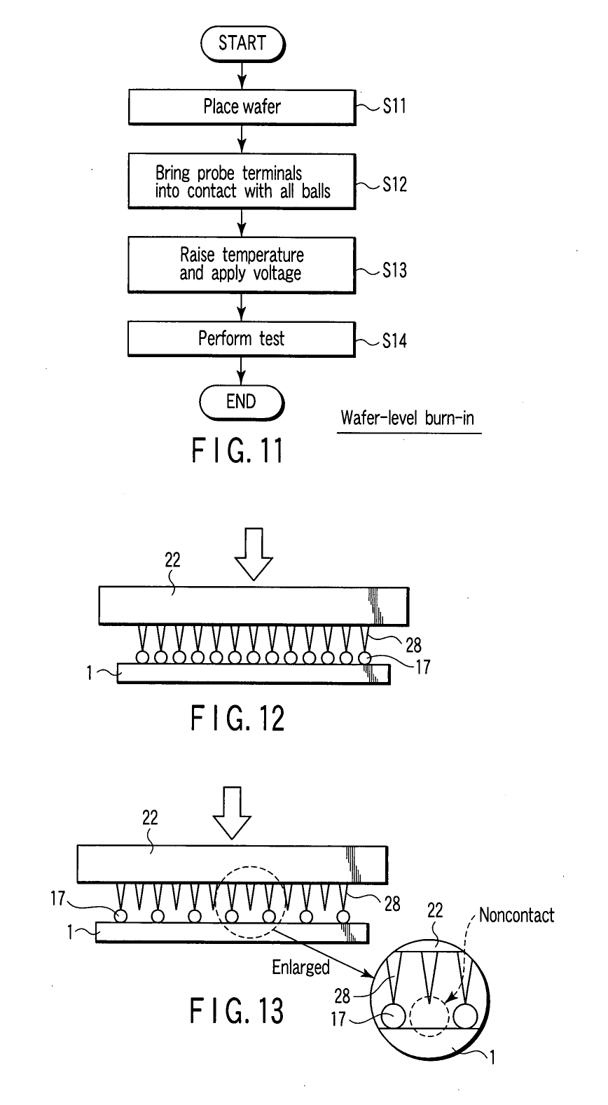

The detail inspection board 23 and the connecting state between the inspection board 23 and the probe card 22 will be described with reference to FIG. 10. FIG. 10 is a perspective view showing the probe card 22 and the inspection board 23, and FIG. 10 schematically shows the connection between the probe card 22 and the inspection board 23.

As shown in FIG. 10, the inspection board 23 includes plural inspection circuits 30. The inspection circuit 30 properly applies the power supply voltage and ground voltage and the signals such as the clock signal, imparted from the power supply unit 25, to each of the probe terminals 28. That is, the inspection board 23 determines what voltage or signal is applied to which probe terminal, and the inspection board 23 applies to the determined voltage or signal to each probe terminal 28. Each inspection circuit 30 of the inspection board 23 and each probe terminal 28 of the probe card 22 are electrically connected by an extraction wiring 31. The inspection circuit 30 and the probe terminal 28 may be provided in one-on-one manner, or the inspection circuit 30 may be provided in each chip 2. In the configuration of the first embodiment, because the probe card 22 has the many probe terminals 28, the inspection circuits 30 are hardly formed on the probe card 22. Therefore, the inspection circuits 30 are formed on the inspection board 23 whose surface area is larger than that of the probe card 22, and the probe terminal 28 and the inspection circuit 30 are connected by the extraction wiring 31.

The wafer-level burn-in test performed by the burn-in apparatus 20 of FIGS. 7 to 10 will be described below. FIG. 11 is a flowchart showing the wafer-level burn-in test, and FIG. 11 shows contents of Step S3 shown in FIG. 1.

As shown in FIG. 11, the wafer 1 in which the balls 17 are formed is placed on the stage 21 of the burn-in apparatus 20 (Step S11). When the load unit 24 applies the load onto the inspection board 23, the load is also applied to the probe card 22 fixed to the inspection board 23, which brings the probe terminal 28 into contact with the wafer 1 (Step S12). FIG. 12 shows the state in which the probe terminal 28 contacts the wafer 1. FIG. 12 is a sectional view showing the probe card 22 and the wafer 1. FIG. 12 shows the case in which the interval d1 between the adjacent probe terminals 28 is equal to the interval between the adjacent balls 17. As shown in FIG. 12, the probe terminals 28 contact the balls 17 respectively. Then, the temperature of the wafer 1 is raised, and the voltage is applied to the wafer 1 (Step S14). That is, in step S14, the temperature in the oven 26 is raised, thereby raising the temperature of the wafer 1. Additionally the voltage and signal generated by the power supply circuit 26 are supplied to the wafer 1 through the control circuit 25, the inspection board 23, and the probe card 22. Therefore, the wafer 1 is heated to raise the temperature of the wafer 1 by itself. As a result, the wafer 1 is heated to the temperature necessary for the test, and the test is performed in that state (Step S14).

Thus, the following effects (1) to (3) are obtained in the semiconductor device fabricating method and the semiconductor device testing apparatus according to the first embodiment.

(1) The burn-in test can collectively be performed on the system LSI in the wafer state.

In the first embodiment, the probe terminals 28 are arranged at equal intervals in the probe card 22. The balls 17 are also arranged at equal intervals in the wafer 1, and the interval between the balls 17 is equal to the interval between the probe terminals 28 or an integral multiple number of the interval between the probe terminals 28. Therefore, the probe terminals 28 can contact all the balls 17, and the burn-in test can collectively be performed on the system LSI at the wafer state.

Conventionally, because the burn-in test is hardly performed on the system LSI at the wafer level, usually the system LSI is divided into individual chips (dicing process) and the burn-in test is performed after the packaging. This is because, in the system LSI, the numerous voltages and signals are used as compared with the semiconductor memory, and each chip has numerous external connecting terminals. As the burn-in test is performed on the system LSI at the wafer level, the number of probe terminals 28 is increased by just much due to the numerous external connecting terminals. In the conventional system LSI, usually pad-shaped terminal is used as the external connecting terminal. Because a pad size usually ranges from tens micrometers to about 100 micrometers, it is also difficult to establish alignment between the pad and the probe terminal. Therefore, conventionally the burn-in test is hardly performed on the system LSI at the wafer level.

However, in the configuration of the first embodiment, the ball 17 is used as the external connecting terminal in the wafer 1. A solder ball used in a ball grid array (BGA) can be used as an example of the ball 17, and the ball 17 has a diameter of about hundreds micrometers. For example, the balls 17 are arrayed at 0.5-mm intervals. The size of the ball 17 is about ten times as large as the pad, and the alignment is easily established between the pad and the probe terminal. That is, the problems in the conventional technique are solved. Therefore, when the balls 17 and the probe terminals 28 are arrayed at equal intervals using the wafer 1 having the configuration of the first embodiment, the burn-in test can collectively be performed at the wafer level.

(2) System LSI fabricating cost can be reduced.

As described in effect (1), in the first embodiment, the screening of the defective chip can be performed at the wafer level. The subsequent packaging process and the like are not required for the defective chip. That is, because the defective chip can be screened before value is added, the unnecessary process can be eliminated to reduce the system LSI fabricating cost.

(3) Test reliability can be improved.

In the first embodiment, the interval between the balls 17 is equal to the interval d1 between the probe terminals 28 as shown in FIG. 12. However, as described above, the interval between the balls 17 has only to be equal to an integral multiple number of the interval d1 between the probe terminals 28. FIG. 13 is a sectional view and a partially enlarged view showing the wafer 1 and probe card 22 when the probe terminals 28 contact the balls 17, and FIG. 13 shows the case in which the interval between the balls 17 is double the interval d1 between the probe terminals 28.

As shown in FIG. 13, every two probe terminals 28 contact the balls 17. At this point, the probe terminal 28 (not used), which does not contact the ball 17, does not contact the wafer 1. That is, some of the plural probe terminals 28 contact the wafer 1. Because the ball 17 has the relatively large diameter of about hundreds micrometers, the probe terminal 28 is too short to contact the wafer even if the load is applied onto the probe card 22. Thus, the probe terminal 28, which is not used, can be prevented from contacting the wafer 1 to improve the burn-in test reliability.

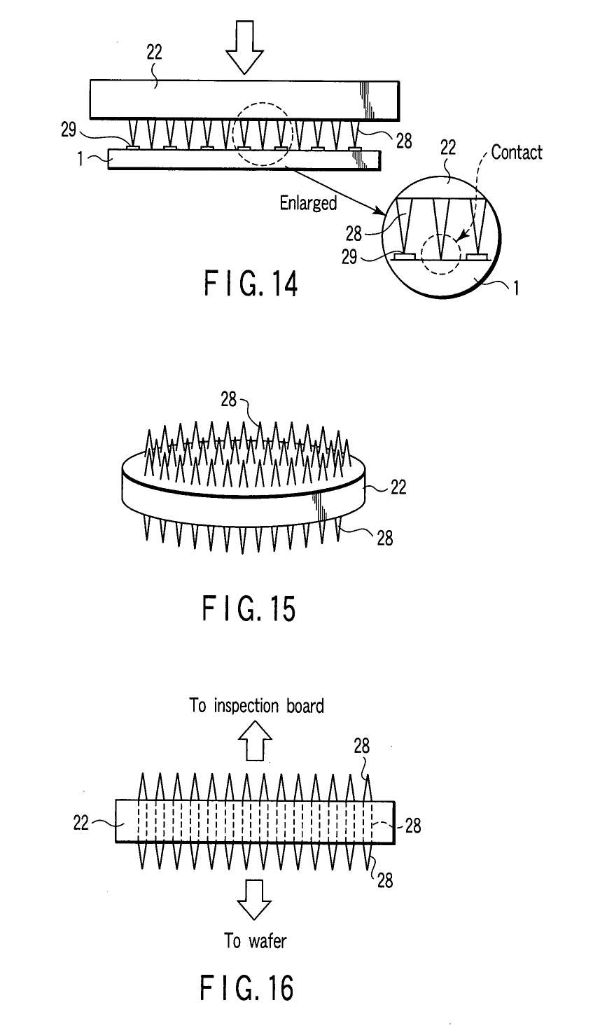

Conversely, a problem arises from the viewpoint of reliability when the pad, not the ball 17, is used as the external connecting terminal. FIG. 14 shows the case in which a pad 29 is used as the external connecting terminal in the same condition as that of FIG. 13. As shown in FIG. 14, because the pad 29 has an extremely low profile from the surface of the wafer 1 as compared with the ball 17, the probe terminal 28 which is not used also contacts the wafer 1. As a result, there is a risk of an unstable burn-in test.

Thus, the use of the ball 17 contributes to the improvement in the burn-in test reliability.

### Second Embodiment

A semiconductor device fabricating method and a semiconductor device testing apparatus according to a second embodiment of the invention will be described below. The second embodiment relates to a configuration of a probe card. In the probe card 22 according to the first embodiment, the probe card 22 and the inspection board 23 are connected with the probe terminal 28. In the second embodiment, only the point different from the first embodiment will be described.

FIGS. 15 and 16 are a perspective view and a sectional view showing the probe card 22 of the second embodiment respectively. FIG. 15 shows the surface which contacts the inspection board 23. As shown in FIG. 15, in the configuration shown in FIGS. 8 and 9 described in the first embodiment, the probe card 22 according to the second embodiment has the configuration in which the probe terminals 28 are projected from not only the surface which contacts the wafer 1 but also the surface which contacts the inspection board 23. As shown in FIG. 16, the probe terminals 28 pierce through the probe card 22, the probe terminals 28 contact the inspection board 23 in the portions projected from the upper surface, and the probe terminals 28 contact the wafer 1 in the portions projected from the lower surface. The plane configurations of both surfaces of the probe card 22 are similar to that of FIG. 9.

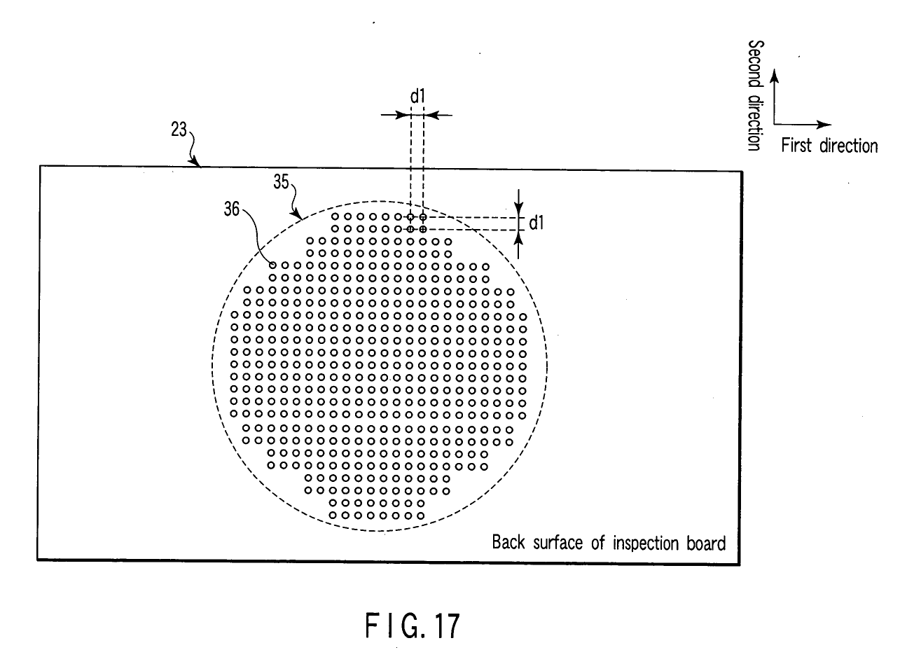

FIG. 17 is a plan view showing the surface which contacts the back surface of the inspection board 23 of the second embodiment, i.e., the surface which contacts the probe card 22. As shown in FIG. 17, a contact terminal region 35 is provided in the back surface of the inspection board 23. In the contact terminal region 35, contact terminals 36 formed by metal pads are two-dimensionally arrayed. An array pattern of the contact terminals 36 is similar to the array pattern of the probe terminals 28 shown in FIG. 9. That is, the contact terminals 36 are arrayed at intervals of d1. Each contact terminal 36 is connected to an internal interconnection (not shown) and the inspection circuit 30 which are formed in the inspection board 23. Similarly to the first embodiment, the inspection circuit 30 may be provided in each contact terminal 36, or the inspection circuit 30 may be provided in a unit of the plural contact terminals 36.

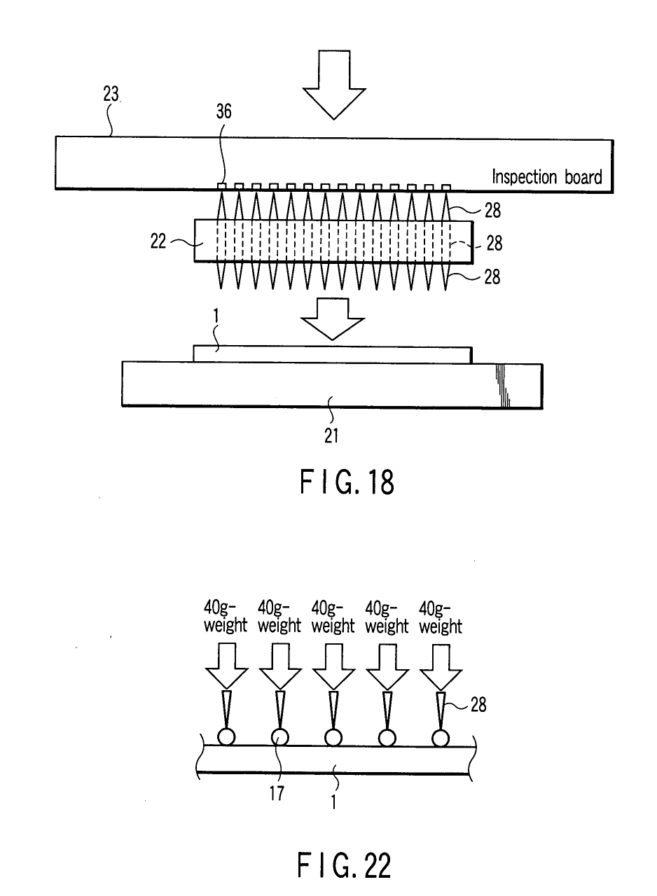

FIG. 18 shows the state of step S11 (see FIG. 11) during the burn-in test in the second embodiment, and FIG. 18 is a sectional view showing the wafer 1, the stage 21, the probe card 22, and the inspection board 23. The balls 17 are omitted in FIG. 18. As shown in FIG. 18, the probe card 22 contacts the inspection board 23 during the burn-in test. At this point, the probe terminal 28 of the probe card 22 is connected so as to contact the contact terminal 36 of the inspection board 23. This enables the probe terminals 28 to be electrically connected to the inspection circuits 30 on the inspection board 23.

In this state of things, the load unit 24 applies the load to the inspection board 23. As a result, in the probe terminal 28, an end portion opposite one end contacting the inspection board 23 contacts the ball 17 projected from the wafer 1, thereby performing the burn-in test.

Other configurations and operations are similar to those of the first embodiment.

Thus, in addition to effects (1) to (3), the following effect (4) is obtained in the semiconductor device fabricating method and the semiconductor device testing apparatus of the second embodiment.

(4) The burn-in test can be simplified.

In the configuration of the second embodiment, the inspection board 23 and the probe card 22 are electrically connected by bringing the probe terminal 28 into contact the contact terminal 36 on the inspection board 23. Accordingly, when the probe card 22 is fixed to the burn-in testing apparatus 20, the switching of the test in each product is completed only by replacing the inspection board 23 with one which is suitable to the kind of the product, so that the burn-in test can be simplified.

### Third Embodiment

A semiconductor device fabricating method and a semiconductor device testing apparatus according to a third embodiment of the present invention will be described below. The third embodiment relates to a burn-in apparatus. In the burn-in apparatus 20 of the first embodiment, the stage 21 functions as the oven 26. In the third embodiment, only the point different from the first embodiment will be described.

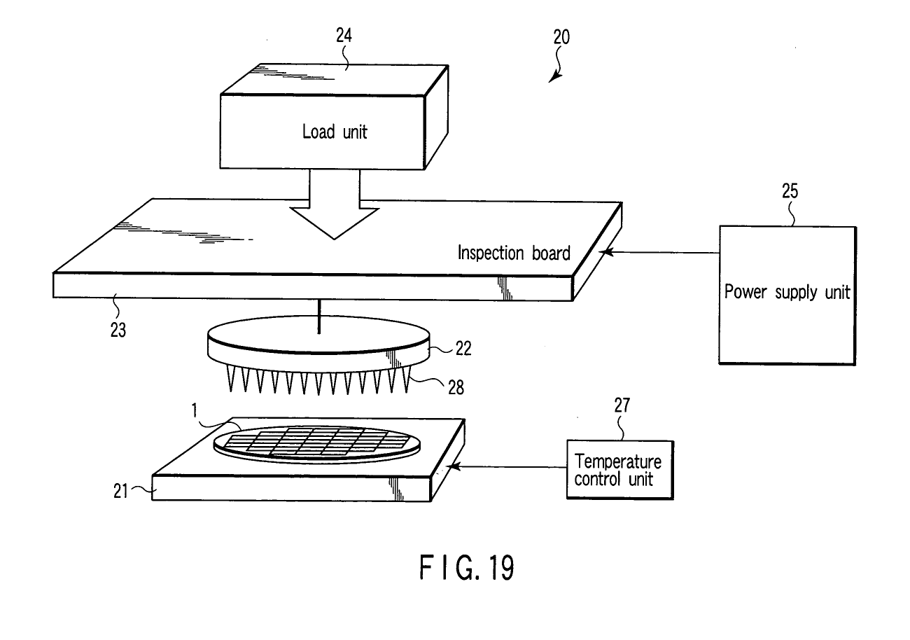

FIG. 19 is a block diagram showing the burn-in apparatus 20 of the third embodiment. As shown in FIG. 19, the configuration of the third embodiment differs from that of the first embodiment in that the oven 26 is eliminated while a temperature control unit 27 is newly provided. While the wafer 1 is placed on the stage 21, the stage 21 acts as the oven 26. That is, in the stage 21, a surface temperature is variable and the surface temperature is controlled by the temperature control unit 27. During the burn-in test, the stage 21 raises the temperature of the wafer 1.

Other configurations and operations are similar to those of the first embodiment.

Thus, in addition to effects (1) to (3) described in the first embodiment, the following effect (5) is obtained in the semiconductor device fabricating method and the semiconductor device testing apparatus according to the third embodiment.

(5) Power consumption can be reduced during the burn-in test.

In the burn-in test, the voltage is applied to LSI while LSI is heated, and LSI is operated under the strict condition to LSI to screen the defective LSI. For example, when LSI has an operation compensation temperature of 150° C., the burn-in test is performed while the temperature of LSI is set to around 150° C., which allows a test time to be shortened.

At this point, in order to heat the LSI to 150° C., ambient temperature of LSI is set to about 75° C. by the oven. Then, the voltage is applied to LSI such that the temperature is raised to about 75° C. by the heat generation of LSI. Thereby, the temperature of the LSI becomes around 150° C. This is because both the inspection board 23 and LSI are located in the oven.

In the case where the burn-in test is performed at the wafer level, because the wafer includes extremely numerous chips 2, it is necessary that the voltage be applied to each chip 2 such that each chip 2 is heated to about 75° C. Therefore, power consumption is possibly increased in the burn-in test at the wafer level.

However, in the third embodiment, the oven 26 is eliminated and the wafer 1 is heated by the stage 21. Because only the wafer 1 is heated, the inspection board 23 is kept at a significantly lower temperature as compared with the conventional burn-in test. That is, because it is not necessary to take into account the temperature of the inspection board 23, the stage 21 can heat the wafer 1 to around 150° C. In other words, it is not necessary that the voltage is applied from the outside to generate the heat of the wafer 1 by itself. Accordingly, the voltage, which should be applied to the wafer 1, can be decreased to reduce the power consumption during the burn-in test.

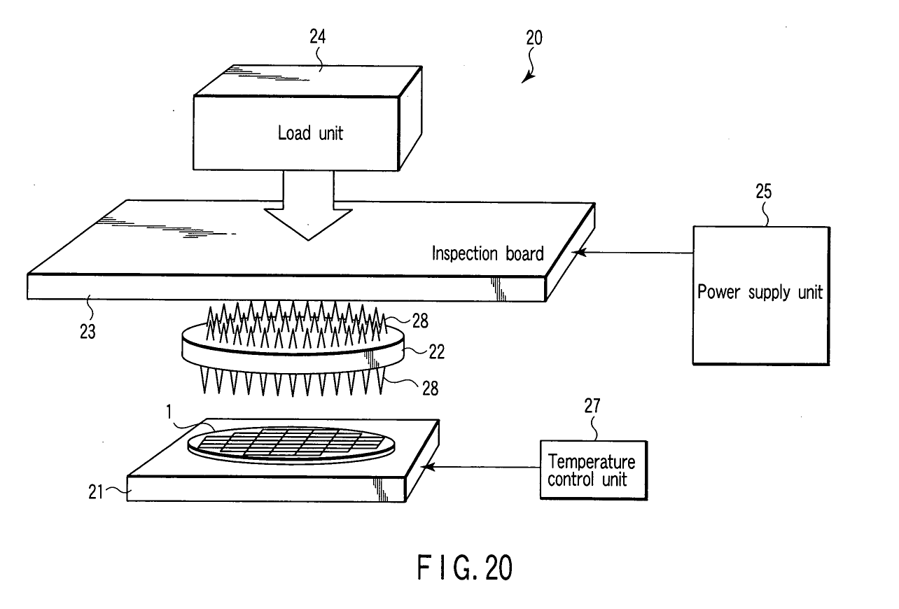

The third embodiment can also be applied to the configuration of the second embodiment. FIG. 20 is a block diagram showing the semiconductor device testing apparatus 20 according to a modification of the third embodiment. As shown in FIG. 20, in the configuration of the third embodiment of FIG. 19, the probe card 22 and the inspection board 23 may be replaced with the configuration of the second embodiment. In this case, in addition to effects (1) to (3) described in the first embodiment and effect (5) described in the third embodiment, effect (4) described in the second embodiment is simultaneously obtained.

### Fourth Embodiment

A semiconductor device fabricating method and a semiconductor device testing apparatus according to a fourth embodiment of the present invention will be described below. The fourth embodiment relates to the burn-in apparatus 20. The load is not applied to the inspection board 23 in a configuration of the burn-in apparatus of the fourth embodiment. In the fourth embodiment, only the point different from the first embodiment will be described.

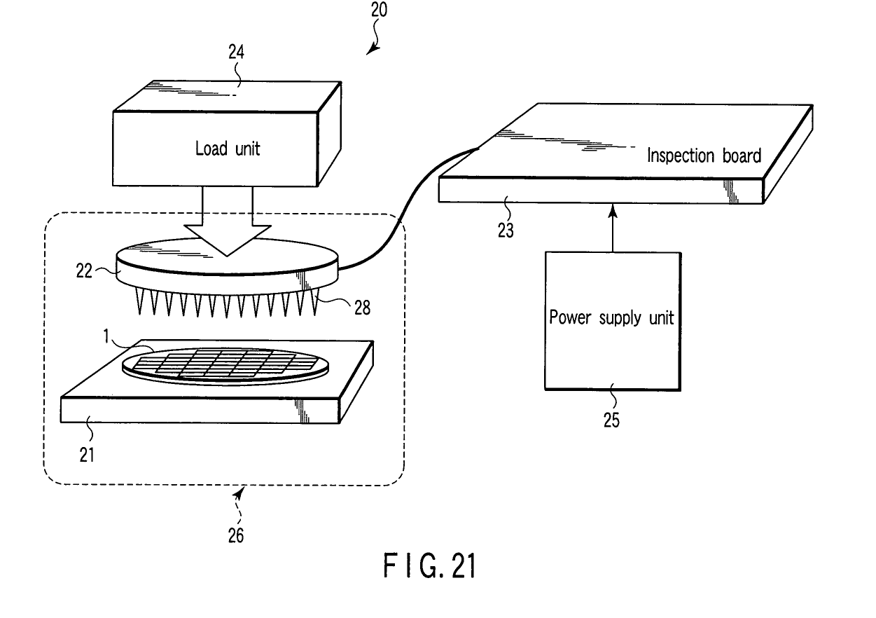

FIG. 21 is a block diagram showing the semiconductor device testing apparatus 20 according to a fourth embodiment. As shown in FIG. 21, the configuration of the fourth embodiment differs from that of the first embodiment in that the inspection board 23 is located in a place except for the place above the probe card 22. In other words, the inspection board 23 is located at the position where the load is not applied to the inspection board 23 by the load unit 24. Although the inspection board 23 is located outside the oven 26 in FIG. 21, the inspection board 23 may be located in the oven 26. In the fourth embodiment, the load unit 24, for example directly, applies the load onto the probe card 22 without applying the load onto the inspection board 23 in step S12 described by using FIG. 11. A fixing member for fixing the probe card 22 may be provided between the load unit 24 and the probe card 22 as long as the load unit 24 does not apply the load on to the inspection board 23. Obviously the probe card 22 and the inspection board 23 are connected by the extraction wiring 31 of FIG. 10.

Other configurations and operations are similar to those of the first embodiment.

Thus, in addition to effects (1) to (3) described in the first embodiment, the following effect (6) is obtained in the semiconductor device fabricating method and the semiconductor device testing apparatus according to the fourth embodiment.

(6) Stress can be reduced during the burn-in apparatus.

In the fourth embodiment, the burn-in apparatus 20 has the configuration in which the load is not applied to the inspection board 23 by the load unit 24. Accordingly, breakage of the inspection board 23 or the decrease in operation reliability due to the stress can be prevented.

Usually, in the burn-in test, usually the predetermined load is applied to the probe terminal 28 in order to securely bring the probe terminal 28 into contact with the external connecting terminal. FIG. 22 shows the state at that time, and FIG. 22 is a sectional view showing the wafer 1 and the probe terminal 28 when the load is applied. As shown in FIG. 22, an approximately 40 gram-weight load is applied to each probe terminal 28. In the case of the system LSI, the number of balls 17 becomes 126000 in total when the balls 17 are arrayed at 0.5 mm intervals in an eight-inch wafer. That is, in order to perform the burn-in test at the wafer level, 126000 probe terminals 28 are required at the minimum, and it is necessary that a 40 gram-weight load be applied to each probe terminal 28. As a result, the load imparted by the load unit 24 becomes about five tons (126000×40 gram-weight). That is, when the probe card 22 and the inspection board 23 are integrally fixed to each other, the five-ton load is also applied to the inspection board 23. Therefore, the inspection board 23 is possibly subjected to large stress.

However, in the configuration of the fourth embodiment, the probe card 22 and the inspection board 23 are separated from each other, and the load is not applied to the inspection board 23 by the load unit 24. Accordingly, breakage or the decrease in operation reliability or stability due to the load can be prevented in the inspection board 23. Obviously, in the wafer 1, because only a 40 gram-weight load is applied to the individual ball 17, there is generated no particular problem.

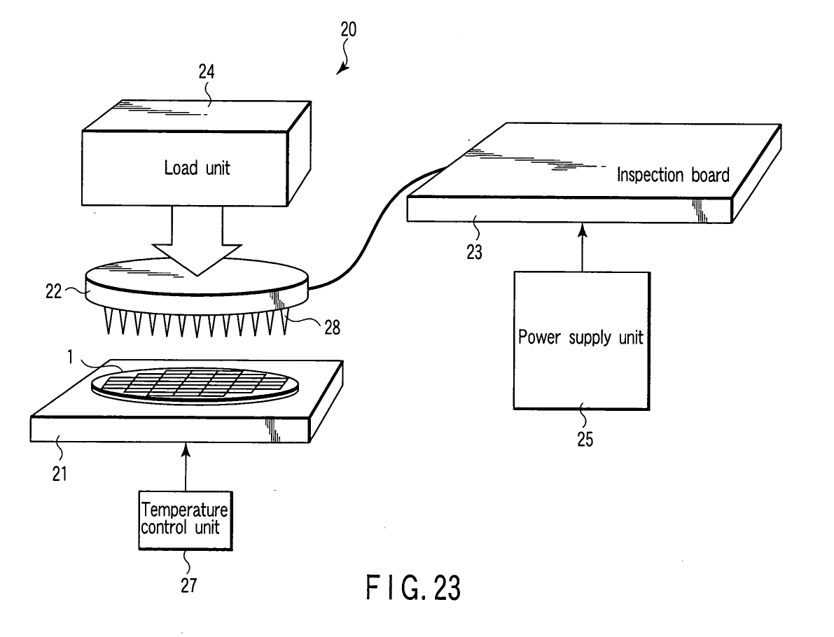

Although the fourth embodiment is applied to the burn-in apparatus of the first embodiment, obviously the fourth embodiment may be applied to the burn-in apparatus of the third embodiment in which the oven 26 is eliminated while the wafer 1 is heated by the stage 21. FIG. 23 shows the configuration in this case, and FIG. 23 is a block diagram showing the semiconductor device testing apparatus 20 according to a modification according to the fourth embodiment. As shown in FIG. 23, in the modification of the fourth embodiment, the inspection board 23 is located in the place except for the place above the probe card 22. Thus, in addition to effects (1) to (3) described in the first embodiment and effect (6) described in the fourth embodiment, effect (5) described in the third embodiment can simultaneously be obtained.

### Fifth Embodiment

A semiconductor device fabricating method and a semiconductor device testing apparatus according to a fifth embodiment of the invention will be described below. Similarly to the fourth embodiment, the fifth embodiment relates to a configuration in which the load is not applied to the inspection board 23 in the structure according to the second embodiment. In the fifth embodiment, only the point different from the second embodiment will be described.

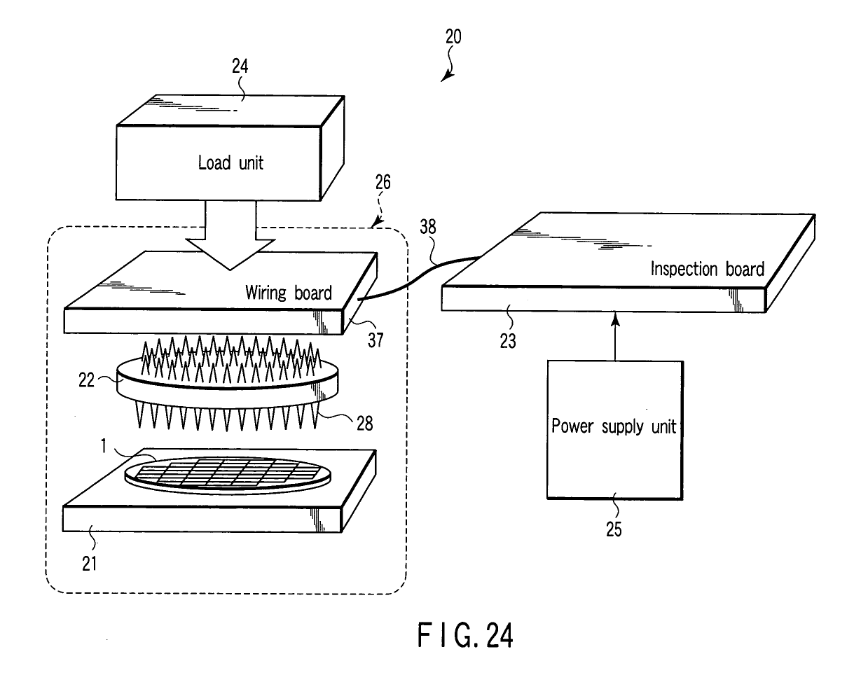

FIG. 24 is a block diagram showing the semiconductor device testing apparatus 20 according to the fifth embodiment. As shown in FIG. 24, the configuration according to the fifth embodiment differs from that of the second embodiment in that a wiring board 37 is newly provided. Similarly to the inspection board 23 of the second embodiment, the contact terminals 36 are provided in the wiring board 37, and the wiring board 37 and the probe terminal 28 are electrically connected by bringing the contact terminal 36 and the probe terminal 28 into contact with each other.

On the other hand, the contact terminals 36 are not required for the inspection board 23, and the wiring board 37 and the inspection board 23 are connected by a connecting wiring 38. That is, form the electric standpoint, the wiring board 37 plays only a role in transmitting the signal read from the probe terminal 28 to the inspection circuit 30 on the inspection board 23 or a role in transmitting the signal imparted from the inspection circuit 30 on the inspection board 23 to the probe terminal 28.

The wiring board 37 plays a role in retaining the probe card 22. In the fifth embodiment, the inspection board 23 is located at the position where the load is not applied to the inspection board 23 by the load unit 24. In other words, the inspection board 23 is located in the place except for the place above the probe card 22. Therefore, the wiring board 37 is newly provided to fix the probe card 22. The load unit 24 applies the load to the wiring board 37, whereby the probe terminal 28 of the probe card 22 contacts the ball 17 of the wafer 1.

Other configurations and operations are similar to those of the second embodiment.

Thus, in addition to effects (1) to (3) described in the first embodiment, and effects (4), and (6) described in the second embodiment, the following effect (7) described in the sixth embodiment is obtained in the semiconductor device fabricating method and the semiconductor device testing apparatus of the fifth embodiment.

(7) A flexibility of the inspection can be increased.

As in the fifth embodiment, because the wiring board 37 is newly used, there is generated no particular problem in the size of the inspection board 23. That is, the large inspection board 23, which is hardly used in the conventional technique, can be used because a restriction on the arrangement position of the inspection board 23 is eliminated. As a result, the large-scale inspection circuit 30 can be mounted on the inspection board 23 to improve the flexibility of the inspection.

Accordingly, unless a problem exists in the arrangement, effect (7) can be obtained by providing the wiring board 37 in addition to the inspection board 23 even in the first to third embodiments.

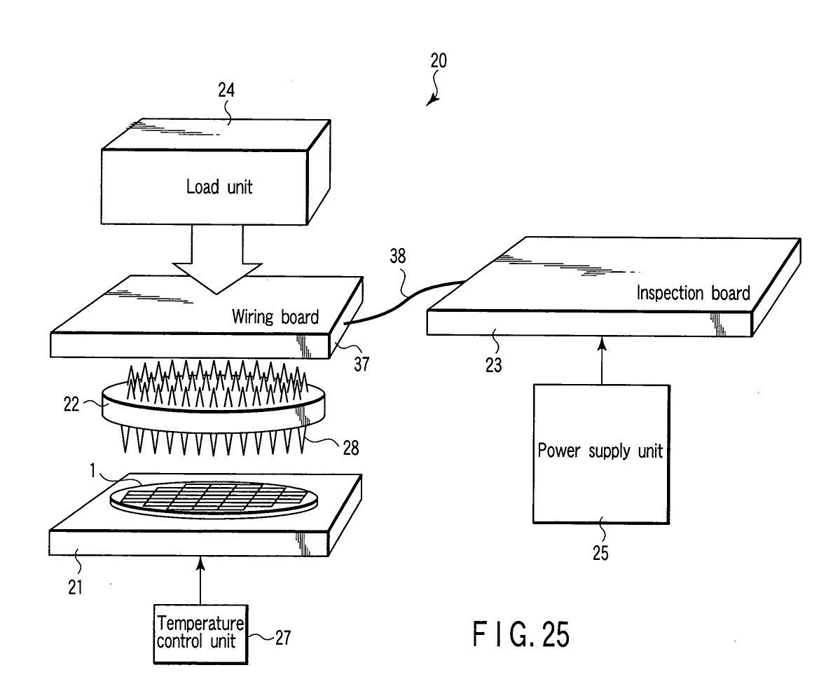

Obviously the fifth embodiment can be applied to the configuration of the modification of the third embodiment in which the oven 26 is eliminated while the wafer 1 is heated by the stage 21. FIG. 25 shows the configuration in this case, and FIG. 25 is a block diagram showing the semiconductor device testing apparatus 20 according to a modification of the fifth embodiment. As shown in FIG. 25, in the configuration of FIG. 24, the oven 26 is eliminated while the temperature control unit 27 is provided, whereby the stage 21 acts as the oven 26. Effects (1) to (7) are obtained in the configuration of the modification of the fifth embodiment.

### Sixth Embodiment

A semiconductor device fabricating method and a semiconductor device testing apparatus according to a sixth embodiment of the present invention will be described below. The sixth embodiment relates to the arrangement of the balls 17 in the wafer 1 of the first to fifth embodiments.

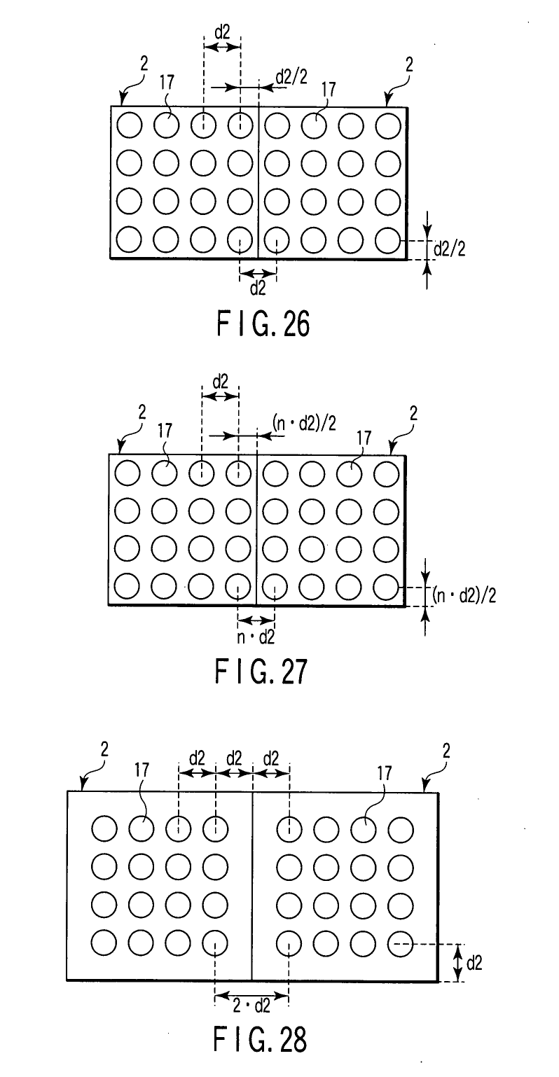

FIG. 26 is a plan view showing the wafer 1 according to a sixth embodiment of the invention, and FIG. 26 shows the arrangement of the balls 17 for the two chips 2. As shown in FIG. 26, the balls 17 are two-dimensionally arrayed in the matrix shape, and an interval between the adjacent balls 17 is equally set to d2. As described above, d2=m·d1 (m is a natural number of one or more), namely, the interval d2 is integral multiple number of the interval d1 between the probe terminals 28. The interval d2 between the adjacent balls 17 is even not only in each chip 2 but also in the wafer 1. Accordingly, the distance from the end portion of the chip 2 to the ball 17 closest to the end portion is d2/2 in the end portion of the chip 2.

FIG. 27 is a plan view showing the wafer 1 of the sixth embodiment of the invention, and FIG. 27 shows a ball arrangement different from that of FIG. 26. As shown in FIG. 27, d2 is the interval between the adjacent balls 17 in each chip 2, (n·d2)/2 (n is a natural number of 2 or more) is the distance from the end portion of the chip 2 to the ball 17 closest to the end portion, and n·d2 is the interval between the adjacent balls 17 across the boundary of the chip 2.

A specific example of the ball arrangement of FIG. 27 will be described with reference to FIG. 28. FIG. 28 is a plan view showing the wafer 1, and FIG. 28 shows the arrangement of the balls 17 for the two chips 2. As shown in FIG. 28, 2·d2 is the interval between the adjacent balls 17 across the boundary of the chip 2. Accordingly, the distance from the end portion of the chip 2 to the ball 17 closest to the end portion becomes d2.

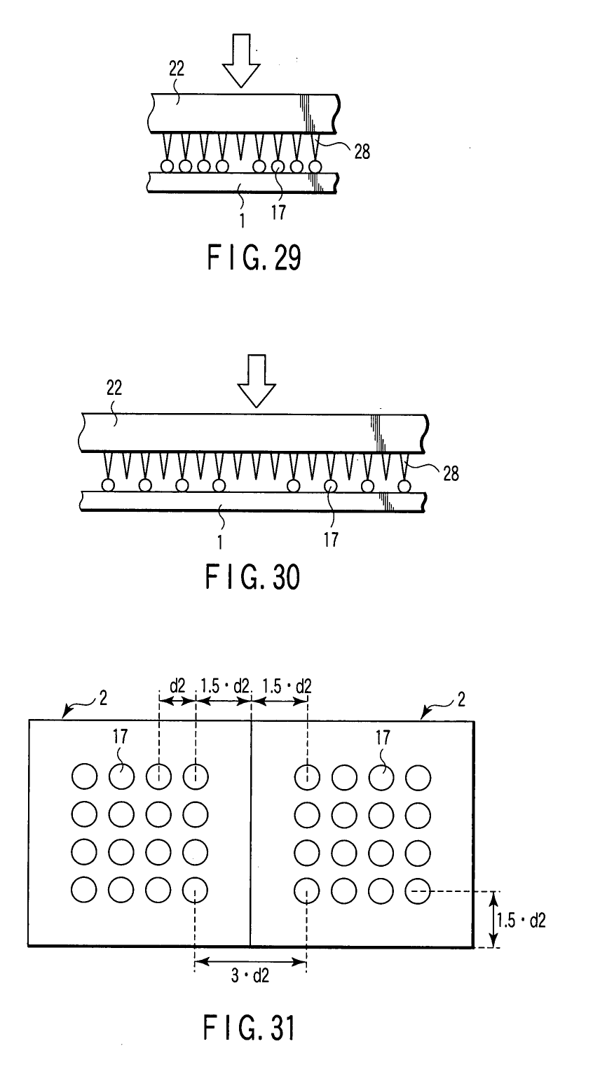

FIG. 29 is a sectional view showing the wafer 1 and the probe card 22 when the burn-in test is performed to the wafer 1 in which the ball arrangement of FIG. 28 is adopted. FIG. 29 shows the case of d1=d2. As shown in FIG. 29, in each chip 2, all the probe terminals 28 contact the balls 17. On the other hand, the boundary portion of the chip 2, the one probe terminal 28 does not contact the ball 17.

FIG. 30 is a sectional view showing the wafer 1 and the probe card 22 during the burn-in test of the wafer 1 in the case where d2 is equal to 2·d1 while the ball arrangement of FIG. 28 is adopted. As shown in FIG. 30, in each chip 2, every two probe terminals 28 contact the balls 17. On the other hand, in the boundary portion of the chip 2, the three probe terminals 28 do not contact the balls 17.

FIG. 31 is a plan view showing the wafer 1 in which a ball arrangement different from that of FIG. 28 is adopted. As shown in FIG. 31, 3·d2 is the interval between the adjacent balls 17 across the boundary of the chip 2. Accordingly, the distance from the end portion of the chip 2 to the ball 17 closest to the end portion becomes 1.5·d2.

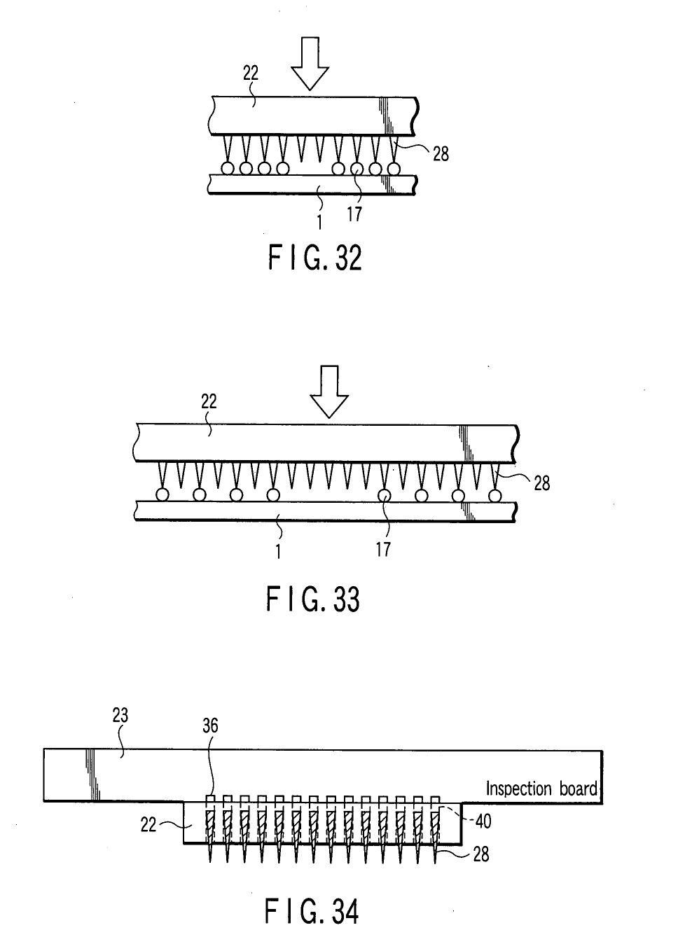

FIG. 32 is a sectional view showing the wafer 1 and the probe card 22 when the burn-in test is performed on the wafer 1 in which the ball arrangement of FIG. 31 is adopted. FIG. 32 shows the case of d1=d2. As shown in FIG. 32, in each chip 2, all the probe terminals 28 contact the balls 17. On the other hand, in the boundary portion of the chip 2, the two probe terminals 28 do not contact the balls 17.

FIG. 33 is a sectional view showing the wafer 1 and the probe card 22 during the burn-in test of the wafer 1 in the case where d2 is equal to 2·d1 while the ball arrangement of FIG. 31 is adopted. As shown in FIG. 33, in each chip 2, every two probe terminal 28 contacts the balls 17. On the other hand, in the boundary portion of the chip 2, the five probe terminals 28 do not contact the balls 17.

Thus, in addition to effects (1) to (7) described in the first to fifth embodiments, the following effect (8) is obtained when the wafer 1 of the sixth embodiment is used in the first to fifth embodiments.

(8) The probe card can be commonly used among the different products to reduce the fabricating cost.

In the sixth embodiment, as shown in FIG. 26, all the intervals between the adjacent balls 17 are equalized in the wafer 1, so that the probe cards 22 described with reference to FIGS. 8, 9, and 15 can commonly be used for the wafer 1 having the ball arrangement of FIG. 26.

Sometimes the chip size or the number of balls depends on the product. In such cases, the arrangement of FIG. 27 can commonly use the probe card 22 in the configurations of FIGS. 8, 9, and 15.

Thus, the need for preparing the probe card in each product is eliminated, so that the fabricating cost of the system LSI can be reduced.

### Seventh Embodiment

A semiconductor device fabricating method and a semiconductor device testing apparatus according to a seventh embodiment of the present invention will be described below. The seventh embodiment relates to another configuration of the probe card of the first to sixth embodiments. In the seventh embodiment, only the point different from the first to sixth embodiments will be described.

FIG. 34 is a sectional view showing the probe card 22 and the inspection board 23 of the seventh embodiment, and FIG. 34 shows the state in which the probe card 22 is fixed to the inspection board 23. As shown in FIG. 34, the probe card 22 includes through-holes 40 piercing therethrough. The needle-shaped probe terminal 28 is movably disposed in the through-hole 40. As described in first and second embodiments, the probe terminals 28 are two-dimensionally arrayed at intervals of d1.

Similarly to the second embodiment, the contact terminals 36 are provided in the back surface of the inspection board 23. The probe card 22 and the inspection board 23 are fixed to each other such that the alignment is established between the through-hole 40 and the contact terminal 36.

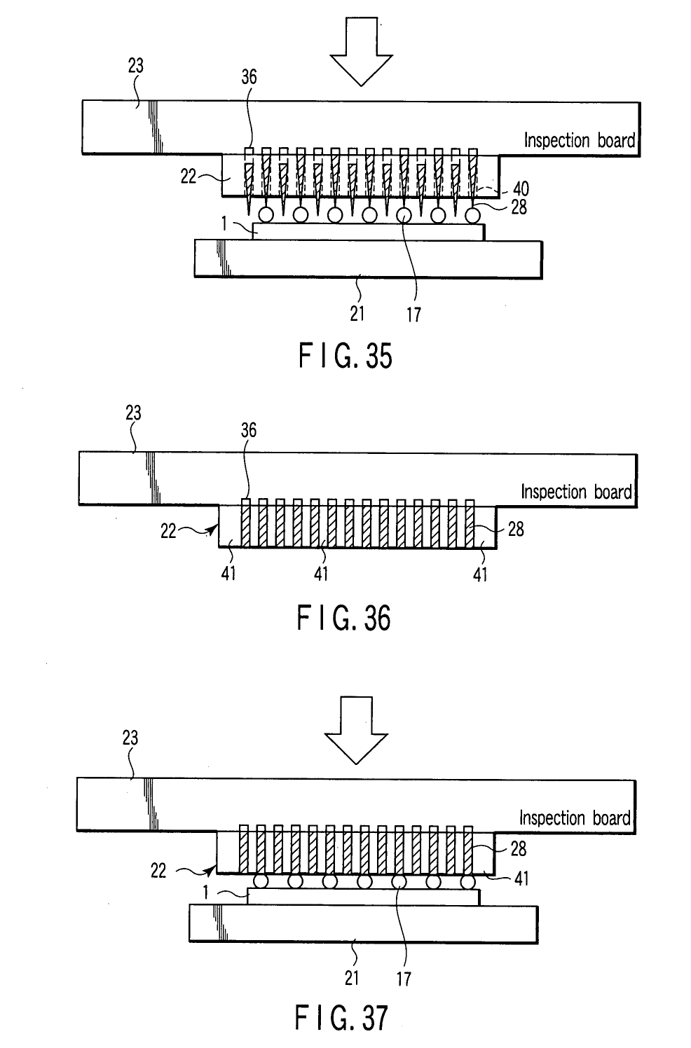

FIG. 35 is a sectional view showing the probe card 22, the inspection board 23, the wafer 1, and the stage 21, and FIG. 35 shows the state in which the load is applied to the probe card 22 and the inspection board 23 to bring the probe terminal 28 into contact with the wafer 1. As shown in FIG. 35, the load is applied to the inspection board 23 and the probe card 22, whereby the probe terminal 28 which contacts the ball 17 is pushed into the through-hole 40 to contact the contact terminal 36 of the inspection board 23. Therefore, the ball 17 is electrically connected to the contact terminal 36 through the probe terminal 28. On the other hand, because the probe terminal 28 which does not contact the ball 17 is not pushed into the through-hole 40, the probe terminal 28 does not contact the contact terminal 36.

Although some of the probe terminals 28 contact the balls 17 in FIG. 35, all the probe terminals 28 may contact the balls 17.

FIG. 36 shows another example of the probe card. FIG. 36 is a sectional view showing the probe card 22 and the inspection board 23 according to the seventh embodiment, and FIG. 36 shows the state in which the probe card 22 is fixed to the inspection board 23. As shown in FIG. 36, the probe terminals 28 piercing through the probe card 22 are embedded in the probe card 22. Both ends of the probe terminal 28 are exposed to the surfaces of the probe card 22. In FIG. 36, the surfaces of both ends of the probe terminal 28 are flash with the surfaces of the probe card 28. Alternatively, the surfaces of both ends of the probe terminal 28 may partially be projected from the surfaces of the probe card 28. An elastic member 41 is provided around the probe terminal 28. For example, a conductive rubber can be used as the elastic member 41. However, any material having elasticity may be used as the elastic member 41. Similarly to the case of FIG. 34, the probe terminals 28 are two-dimensionally arrayed at intervals of d1.

Similarly to the case of FIG. 34, the contact terminals 36 are provided in the back surface of the inspection board 23. The probe card 22 and the inspection board 23 are fixed to each other such that the alignment is established between the one end of the probe terminal 28 and the contact terminal 36.

FIG. 37 is a sectional view showing the probe card 22, the inspection board 23, the wafer 1, and the stage 21, and FIG. 37 shows the state in which the load is applied to the probe card 22 and the inspection board 23 to bring the probe terminal 28 into contact with the wafer 1. As shown in FIG. 37, the other end of the probe terminal 28 is made to contact with the ball 17. At this point, the load applied to the inspection board 23 and the probe card 22, whereby the elastic member 41 contacting the ball 17 is deformed by the elasticity of the elastic member 41.

Although some of the probe terminals 28 contact the balls 17 in FIG. 37, obviously, all the probe terminals 28 may contact the balls 17.

Thus, the probe card 22 of the first to sixth embodiments may be replaced with the probe card 22 of the seventh embodiment.

Thus, in addition to effects (1) to (8), the following effect (9) is obtained by the use of the probe card 22 of the seventh embodiments.

(9) The load for contacting the wafer 1 is easily adjusted.

In the case of the probe card 22 shown in FIG. 34, only the probe terminal 28 contacting the ball 17 is used in the burn-in test, and the probe terminal 28 which does not contact the ball 17 is neither used in the burn-in test nor contacts the contact terminal 36 of the inspection board 23. Accordingly, a clearance between the wafer 1 and the probe card 22 can sufficiently be maintained to easily adjust the load between the wafer 1 and the probe card 22.

In the case of the probe card 22 shown in FIG. 36, because the elastic member 41 is provided around the probe terminal 28, the elastic member 41 absorbs impact when the probe card 22 contacts the ball 17. Accordingly, the load is easily adjusted between the wafer 1 and the probe card 22.

In the seventh embodiment, the probe card 22 is fixed to the inspection board 23. Alternatively, the probe card 22 may be fixed to the wiring board 37 of the fifth embodiment.

Thus, in the semiconductor device fabricating method and semiconductor device testing apparatus of the first to seventh embodiments, the burn-in test can collectively be performed at the wafer level for the system LSI wafer 1 in which the ball-shaped external connecting terminals are arrayed at equal intervals, so that the simplification and the cost reduction can be achieved in the semiconductor device fabricating process.

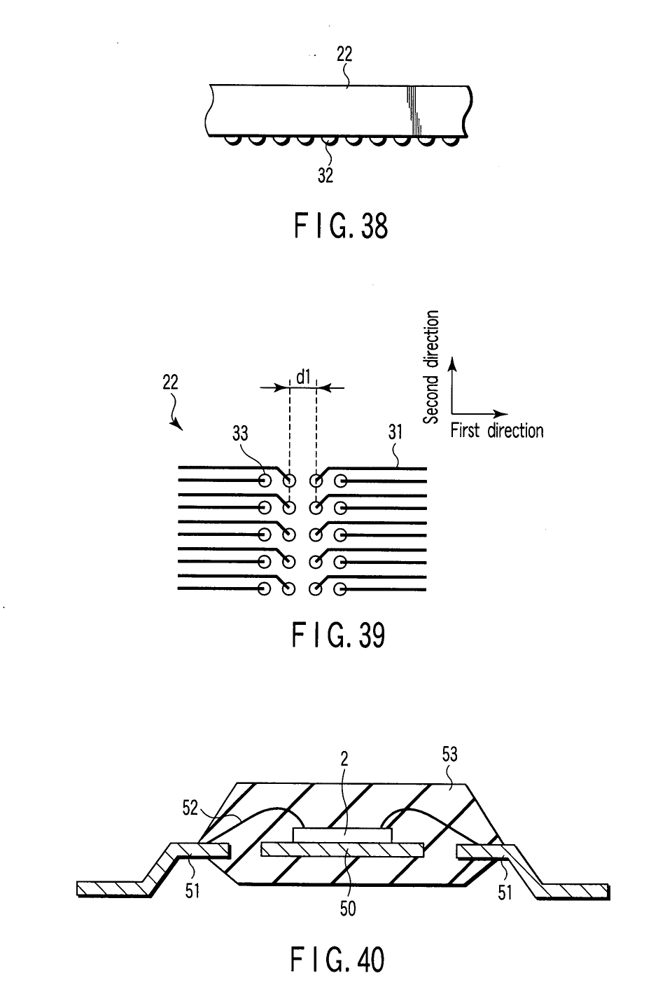

Although the probe terminal 28 is formed in the needle shape in the first to seventh embodiments, the shape of the probe terminal 28 is not particularly limited to the needle shape. For example, as shown in FIG. 38 which is a sectional view showing the probe card 22, a probe terminal 32 may be formed in a hemispherical shape. In this case, materials such as a conductive rubber can be used as the probe terminal 32. The extraction wiring 31 of the first embodiment, which connects the probe card 22 and the inspection board 23, can be arranged as shown in FIG. 39. FIG. 39 is a plan view of the probe card 22, and FIG. 39 is a plan view showing the back surface of the surface in which the probe terminals 28 and 34 are provided. As shown in FIG. 39, through-holes 33 are made in the probe card 22, and the through-hole 33 reaches the probe terminals 28 and 34. The extraction wiring 31 is connected into the through-hole 33. On the probe card 22, the extraction wirings 31 are extracted to the outside while divided into two directions. This is because the interval between the extraction wirings 31 becomes excessively close when all the extraction wirings 31 are extracted in one direction. Obviously the extraction wirings 31 may be extracted not only in the two directions but also in the first and second directions in FIG. 39. The same holds true for the internal line of the wiring board 37 when the wiring board 37 is used.

In the first to seventh embodiments, the probe terminals 28 of the probe card 22 are arrayed at equal intervals of d1. However, similarly to the ball 17, it is not always necessary that the all probe terminals 28 be arrayed at equal intervals. For example, assuming that d (min) is the minimum value of the interval between the adjacent probe terminals 28, the probe terminals 28 may be arrayed at intervals of an integral multiple number of d. The same holds true for the probe terminal 28. The needle-shaped probe terminal 28 of the first to seventh embodiments may be made of the conductive rubber having the elasticity.

Although WCSP is described in the first to seventh embodiments, the burn-in test of the first to seventh embodiments can also be applied to other packages. FIG. 40 is a sectional view showing a quad flat package (QFP). As shown in FIG. 40, the chip 2 is placed on a die pad 50 of a lead frame. The chip 2 has a pad (not shown) which functions as the external connecting terminal on the upper surface of the chip 2. The pad and an inner lead 51 of the lead frame are connected by a bonding wire 52. Then, the chip 2, the die pad 50, the inner lead 51, and the bonding wire 52 are sealed by a resin 53.

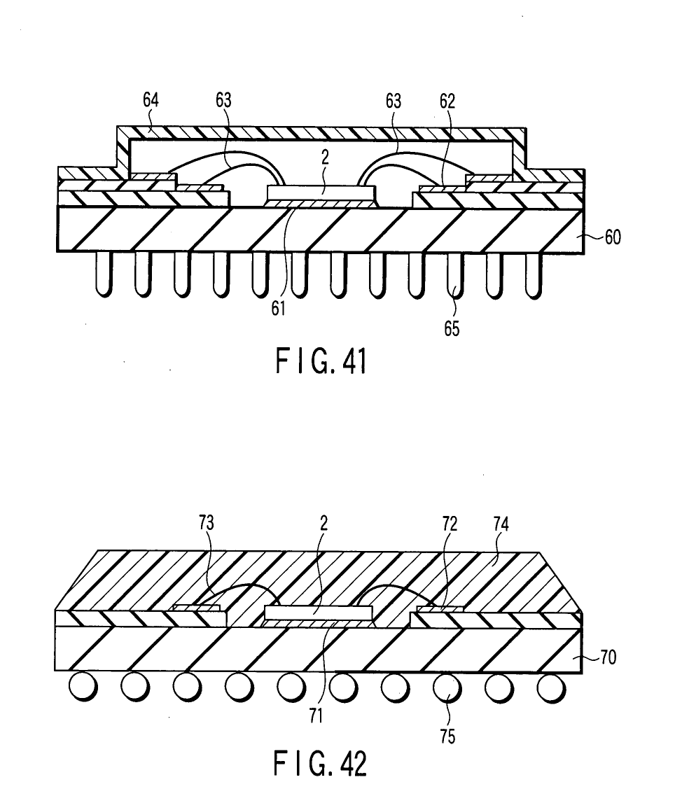

FIG. 41 is a sectional view showing a pin grid array (PGA) which is one kind of QFP. As shown in FIG. 41, the chip 2 is bonded onto a package 60 using a resist 61. Wiring 62 is formed on a main surface of the package 60, a pad (not shown) of the chip 2 and the wiring 62 are connected by a bonding wire 63. Then, the chip 2, the wiring 62, and the bonding wire 63 are sealed using a lid 64. Plural pins 65 are provided in the back surface of the package 60. The wiring 62 and the pin 65 are connected by wiring (not shown) in the package 60 and the pin 65 functions as the external connecting terminal in a PGA.

FIG. 42 is a sectional view of a BGA. As shown in FIG. 42, the chip 2 is bonded onto a package 70 using a resist 71. Wiring 72 is formed on a main surface of the package 70, a pad (not shown) of the chip 2 and the wiring 72 are connected by a bonding wire 73. Then, the chip 2, the wiring 72, and the bonding wire 73 are sealed using a lid 74. Plural pins 75 are provided in the back surface of the package 70. The wiring 72 and the pin 75 are connected by wiring (not shown) in the package 70 and the pin 75 functions as the external connecting terminal in the BGA.

Thus, the burn-in test method according to the first to seventh embodiments can be applied to the chip 2 in which the pad 80, not the ball 17, is provided as long as the trouble as described in FIG. 14 is not generated. Obviously, similarly to a WCSP, the balls 17 may be provided on the chip 2 in the package structures described in FIGS. 40 to 42.

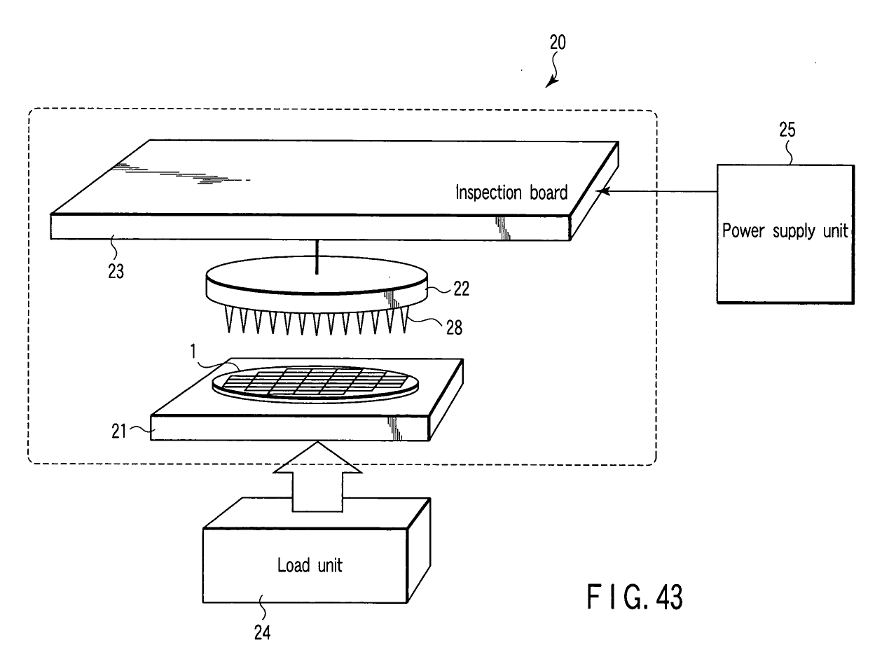

In the first to seventh embodiments, the load is applied to the probe card 22 by the load unit 24 disposed above the probe card 22. Alternatively, the load may be applied to the stage 21. The case in which the load is applied to the stage 21 will be described with reference to FIG. 43. FIG. 43 is a block diagram showing the semiconductor device testing apparatus 20 according to a modification of the first embodiment.

As shown in FIG. 43, in the configuration of the first embodiment shown in FIG. 7, the load unit 24 may be disposed below the stage 21. That is, the load unit 24 and the probe card 22 are provided on the respective sides of the stage 21. The load unit 24 does not directly apply the load to the probe card 2, but applies the load to the stage 21. Even in the configuration, the burn-in test of the first embodiment can be performed. In addition to the burn-in apparatus of FIG. 7, the load unit 24 may also apply the load to the stage 21 in the pieces of apparatus shown in FIGS. 18 to 21, 23 to 25, 34, and 37. Thus, in the configuration of FIG. 43, preferably the load is not directly applied to the inspection board 23.

It is not always necessary that the burn-in test of the first to seventh embodiments be performed at the wafer level, but the burn-in test may be performed in the package state. The burn-in test in the package state will be described as an eighth embodiment.

### Eighth Embodiment

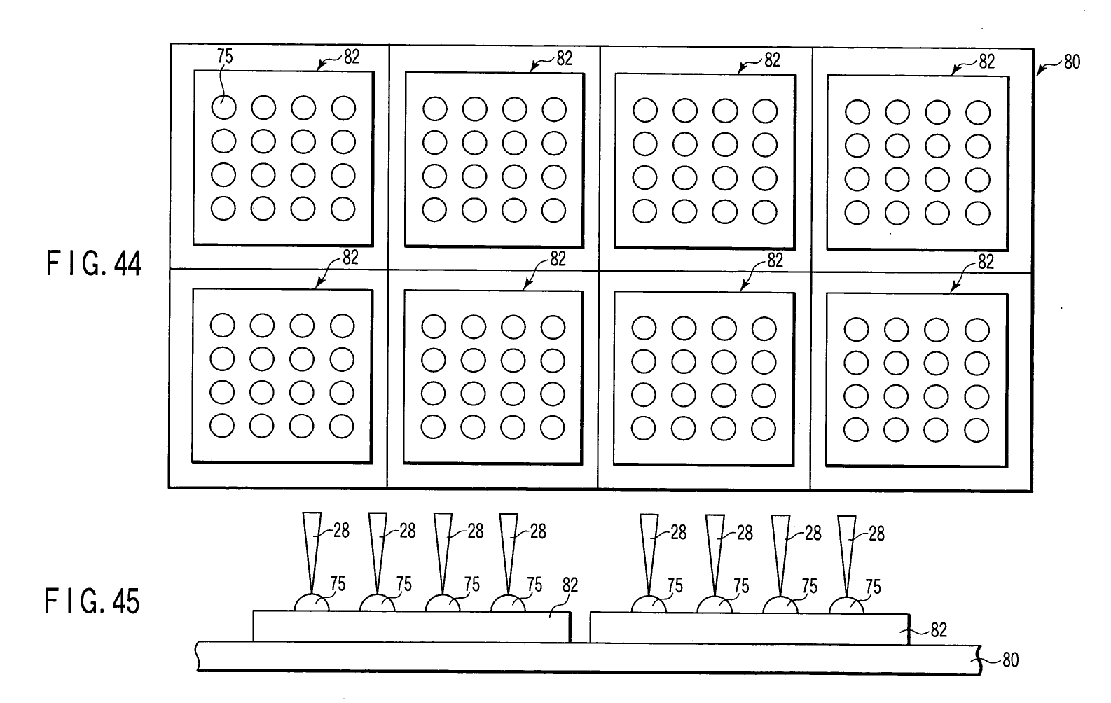

FIGS. 44 and 45 are schematic views showing a state when the burn-in test is performed on a BGA in which the packaging is completed.

As shown in FIG. 44, the plural BGAs 82 are mounted on a tray 80. BGA 82 has the configuration of FIG. 42, and BGAs 82 are mounted on the tray 80 in the matrix shape while the balls 75 are located in the upper surface. The tray 80 in which BGAs 82 are mounted is put in the burn-in apparatus 20.

FIG. 45 shows a state in which the probe terminals 28 contact BGAs 82 on the tray 80 in the burn-in apparatus 20. As shown in FIG. 45, the probe terminals 28 contact all the balls 75 of BGAs 82. It is necessary that the distance between the adjacent balls 75 in the different BGAs 82 be an integral multiple number of the interval between the probe terminals 28. This is similar to the way of thinking of FIGS. 28 to 33.

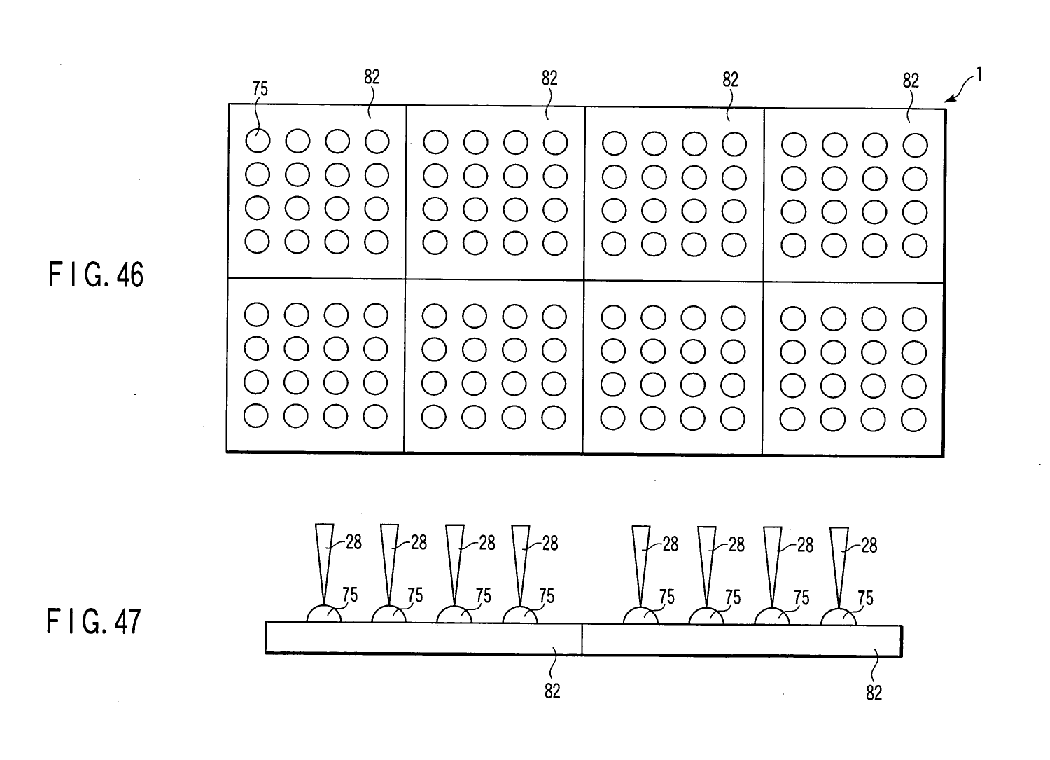

The first to seventh embodiments can be applied to BGAs 82 at the state before BGAs 82 are divided into the individual packages. The description will be made at point with reference to FIGS. 46 and 47.

FIGS. 46 and 47 are schematic views showing a state when the burn-in test is performed on BGAs 82 which are not separated into the individual packages yet.

As shown in FIG. 46, BGAs 82 are not separated into the individual packages yet, but integrally formed with each other. BGAs 82 of FIG. 46 are put in the burn-in apparatus 20.

FIG. 47 shows a state in which the probe terminals 28 contact the BGAs 82 of FIG. 46 in the probe terminal 82. As shown in FIG. 47, the probe terminals 28 contact all the balls 75 of BGAs 82. This is similar to the way of thinking of FIGS. 28 to 33.

Instead of BGA 82, the method of FIG. 44 can also be applied to the PGA of FIG. 41.

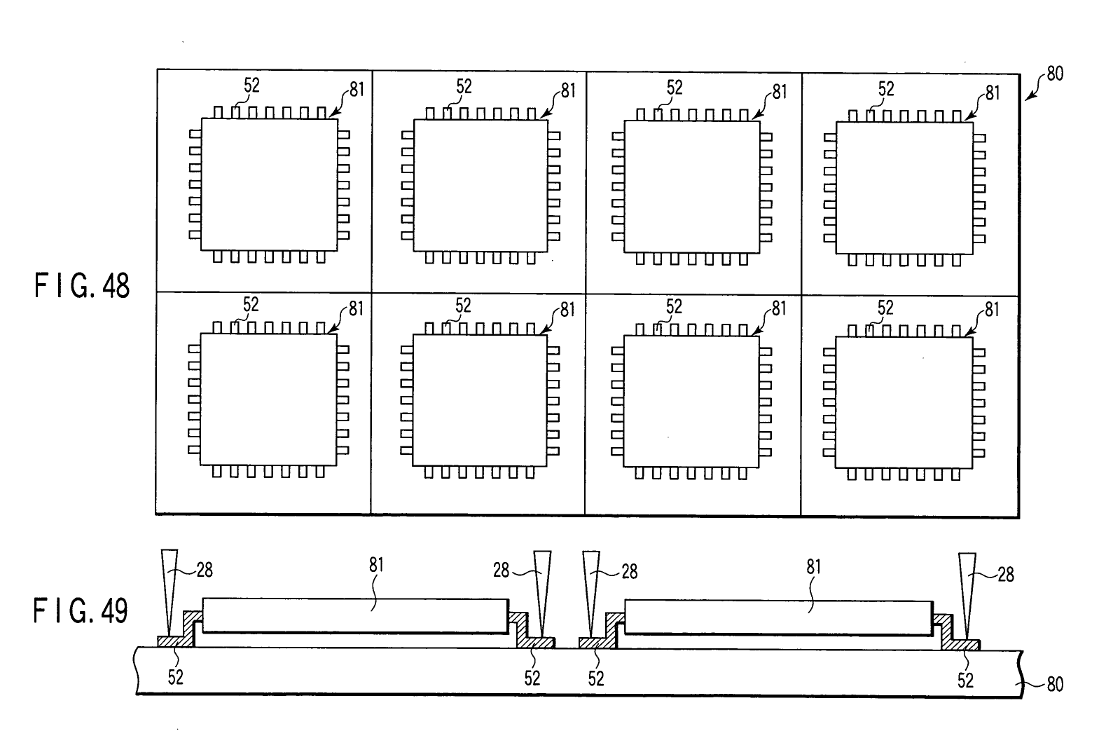

The same holds true for a QFP. FIGS. 48 and 49 are schematic views showing a state when the burn-in test is performed on QFP 81 in which the packaging is completed

As shown in FIG. 48, plural QFPs 81 are mounted on the tray 80. QFP 81 has the configuration of FIG. 40, and QFPs 81 are mounted on the tray 80 in the matrix shape. The tray 80 in which QFPs 81 are mounted is put in the burn-in apparatus 20.

FIG. 49 shows a state in which the probe terminals 28 contact QFPs 81 on the tray 80 in the burn-in apparatus 20. As shown in FIG. 49, in QFP 81, outer leads 52 connected to inner leads 51 are exposed to the outside. The probe terminals 28 contact all the outer leads 52.

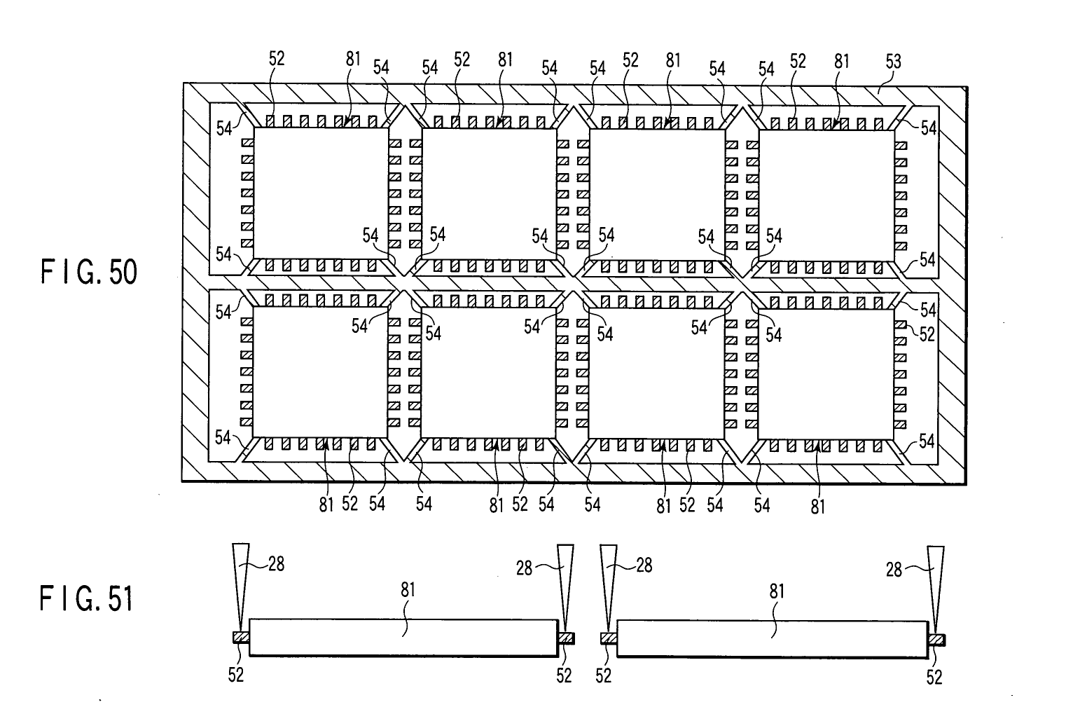

The first to seventh embodiments can be applied to QFPs 81 at the state before QFPs 81 are divided into the individual packages. The description will be made at point with reference to FIGS. 50 and 51.

FIGS. 50 and 51 are schematic views showing a state when the burn-in test is performed on QFPs 81 which are not separated into the individual packages yet.

As shown in FIG. 50, QFPs 81 are not yet separated into the individual packages. That is, QFPs 81 are integrally connected to an outer rim 53 of the lead frame while a dummy terminal 54 is interposed. The dummy terminal 54 is cut in separating QFPs 81 into the individual packages.

FIG. 51 shows the state in which the probe terminals 28 contact QFPs 81 of FIG. 50 in the burn-in apparatus 20. As shown in FIG. 51, the probe terminals 28 contact all the outer leads 52.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for fabricating a semiconductor device comprising:
placing a semiconductor wafer on a stage, the semiconductor wafer having a plurality of ball-shaped external connecting terminals projected from a surface;
bringing a probe card close to the semiconductor wafer placed on the stage to bring a plurality of probe terminals included in the probe card into contact with the external connecting terminals respectively; and
applying a voltage to the semiconductor wafer through the probe terminal to perform a test of the semiconductor wafer, the probe terminals contacting all the external connecting terminals.

2. The method according to claim 1, wherein the probe terminals and the external connecting terminals are arrayed at first intervals or second intervals, the second interval being an integral multiple number of the first interval, and only some of the probe terminals contact the semiconductor wafer.

3. The method according to claim 1, further comprising raising a temperature of the stage to raise a temperature of the semiconductor wafer after the semiconductor wafer is placed on the stage,
wherein the test is performed in a state in which the temperature of the semiconductor wafer is raised by the stage.

4. The method according to claim 1, further comprising dicing the semiconductor wafer to obtain individual semiconductor chips after the test.

5. A semiconductor device testing apparatus which performs a burn-in test to a semiconductor chip in a wafer state, the semiconductor chip having a plurality of ball-shaped external connecting terminals projected from a surface, the apparatus comprising:
a stage on which a semiconductor wafer including the semiconductor chip is placed;
a probe card which has a plurality of probe terminals arrayed two-dimensionally at equal intervals, the probe terminals being able to contact the external connecting terminals of the semiconductor wafer placed on the stage;
a power supply unit which generates a voltage; and
an inspection board which applies the voltage generated by the power supply unit to the individual probe terminal.

6. The apparatus according to claim 5, further comprising a load unit which applies a load onto the probe card to bring the probe terminals into contact with the external connecting terminals of the semiconductor wafer,
wherein the load unit applies the load to the probe card without applying the load to the inspection board.

7. The apparatus according to claim 5, wherein the probe terminals and the external connecting terminals are arrayed at first interval or second interval, the second interval being an integral multiple number of the first interval, and only some of the probe terminals contact the semiconductor wafer.

8. The apparatus according to claim 5, wherein the stage on which the semiconductor wafer is placed, the probe card, and the inspection board are accommodated in an oven when the burn-in test is performed.

9. The apparatus according to claim 5, wherein a surface area of the inspection board is larger than a surface area of the probe card.

10. The apparatus according to claim 5, wherein one ends of the probe terminals are connectable to the external connecting terminal while projected from a main surface of the probe card, and
other ends of the probe terminals are connectable to the inspection board while projected from a back surface of the probe card.

11. The apparatus according to claim 5, further comprising a temperature control unit which controls a temperature of the stage.

12. The apparatus according to claim 5, wherein the stage on which the semiconductor wafer is placed and the probe card are accommodated in an oven, and the inspection board is disposed outside the oven when the burn-in test is performed.

13. The apparatus according to claim 5, further comprising a wiring board which fixes the probe card,
wherein one ends of the probe terminals are connectable to the external connecting terminals while projected from a main surface of the probe card, and other ends of the probe terminals are connectable to the wiring board while projected from a back surface of the probe card, and
the inspection board is electrically connected to the probe terminals through the wiring board.

14. The apparatus according to claim 5, wherein an elastic member is provided around the probe terminals in the probe card.

15. The apparatus according to claim 5, wherein each of the probe terminals has a hemispherical shape projected from a surface of the probe card.
